(19) United States
(12) Patent Application Publication
(10) Pub. No.: US 2025/0173264 A1
(43) Pub. Date: May 29, 2025

(54) LEARNING MEMORY SYSTEMS AND METHODS

(71) Applicant: University of Florida Research Foundation, Inc., Gainesville, FL (US)

(72) Inventors: Swarup Bhunia, Gainesville, FL (US); Prabuddha Chakraborty, Gainesville, FL (US)

(21) Appl. No.: 19/037,772

(22) Filed: Jan. 27, 2025

Related U.S. Application Data
(63) Continuation-in-part of application No. 17/336,944, filed on Jun. 2, 2021.
(60) Provisional application No. 63/033,894, filed on Jun. 3, 2020.

(51) Int. Cl. G06F 12/08

(52) U.S. Cl. CPC G06F 12/08; G06F 2212/1012; G06F 2212/1016

(57) ABSTRACT

Systems and methods are configured for implementing a learning memory system organized as a network of multi-level and heterogeneous cues and dynamic association of cues with data units. In various embodiments, one or more hives are constructed within the memory system. Each hive is responsible for storing data of a particular modality. In addition, one or more localities are constructed for each hive. Each of the localities for a particular hive includes one or more data units that are semantically related and interconnected based on a relation to each other. Each of these data units contains a data element, features of the data element, and parameters relevant to the data element. Further, a cue bank is constructed for each hive to store cues configured to semantically link one or more data units across the various localities for a particular hive.

### CROSS-REFERENCE TO RELATED APPLICATIONS

The present application is a continuation in part of U.S. application Ser. No. 17/336,944, titled “BRAIN INSPIRED LEARNING MEMORY SYSTEMS AND METHODS,” filed Jun. 2, 2021, which claims priority to U.S. Provisional Application Ser. No. 63/033,894, titled “BRAIN INSPIRED LEARNING MEMORY SYSTEMS AND METHODS,” filed Jun. 3, 2020, the entire contents of both of which are incorporated herein by reference.

### TECHNOLOGICAL FIELD

Embodiments of the present disclosure generally relate to computer system memory architectures and frameworks.

### BACKGROUND

The use of conventional computer memory in many applications can be problematic especially when used to store huge amounts of data. For instance, the capturing of image and/or sound data in a monitoring environment can result in huge storage requirements. Many times, a large amount of the data that is stored is of little importance. For example, the majority of image data captured by a security surveillance system may be of little importance since it involves images of activity of no interest (e.g., images of activity when a crime is not being committed).

Storage and retrieval of data in a computer memory plays a major role in system performance. Traditionally, computer memory organization is static (e.g., it does not change based on the application-specific characteristics in memory access behavior during system operation). Specifically, the association of a data block with a search pattern (or cues) as well as the granularity of a stored data do not evolve. Such a static nature of computer memory not only limits the amount of data that can be stored in a given physical storage, but it also misses the opportunity for dramatic performance improvement in various applications.

Accordingly, computer system memory architectures configured to provide plasticity in (i) storing and retrieving data, and (ii) dynamically creating and updating associations between data and corresponding cues would provide advantages over conventional computer system memory architectures. It is with respect to these considerations and others that the disclosure herein is presented.

### BRIEF SUMMARY

Various embodiments of the disclosure are directed to novel computer system memory architectures/frameworks, sometimes referred to herein as learning-based storage (LS), that include memory hives, each for individual data types and containing several localities. In particular embodiments, each of these localities is capable of holding several data units and each data unit contains a single data element along with other parameters. Depending on external stimulus, the data units are added, modified, and/or moved around in various embodiments as described herein.

Embodiments herein organize computing system memory as a flexible neural memory network. The network structure, strength of associations, and granularity of the data adjust continuously during system operation, providing unprecedented plasticity and performance benefits. A formalizing learning process according to embodiments herein includes integrated storage, retrieval, and retention processes. Using a full-blown operational model, embodiments herein are shown to achieve an order of magnitude improvement in memory access performance for two representative applications when compared to traditional content-based memory.

Accordingly, several memory operations are introduced to enable novel memory architectures/frameworks. Various embodiments of the memory architectures are configured to make intelligent decisions via statistical reinforcement learning. In addition, overall memory performance is increased in various embodiments in comparison to conventional computer system memory architectures. Thus, embodiments of the system memory architectures disclosed herein can be used to replace existing conventional computer system memory and can be tuned for specific applications.

### BRIEF DESCRIPTION OF THE SEVERAL VIEWS OF THE DRAWING(S)

Having thus described the disclosure in general terms, reference will now be made to the accompanying drawings, which are not necessarily drawn to scale, and wherein:

FIG. 1A depicts an example memory architecture in accordance with various embodiments of the present disclosure;

FIG. 1B illustrates an example computer memory architecture;

FIG. 1C depicts an example memory architecture in accordance with various embodiments of the present disclosure;

FIG. 1D depicts an example neural memory network (NMN) in accordance with various embodiments of the disclosure.

FIG. 2 is a schematic of a computing entity in accordance with various embodiments of the present disclosure;

FIG. 3A depicts an example external stimulus guided reactional reinforcement learning (RL) architecture for incorporating intelligence, according to various embodiments;

FIG. 3B depicts an example taxonomy of operations in accordance with various embodiments of the present disclosure;

FIG. 3C depicts example processes for use with embodiments of the present disclosure;

FIG. 3D depicts example processes for use with embodiments of the present disclosure;

FIG. 3E depicts example processes for use with embodiments of the present disclosure;

FIG. 4 depicts an example process flow for storing data in accordance with various embodiments of the present disclosure;

FIG. 5 depicts an example process flow for retrieving data in accordance with various embodiments of the present disclosure;

FIG. 6 depicts an example process flow for retaining data in accordance with various embodiments of the present disclosure;

FIG. 7 depicts an example process flow for adding a new association between two data units in accordance with various embodiments of the present disclosure;

FIG. 8 depicts an example process flow for deleting an association between two data units in accordance with various embodiments of the present disclosure;

FIG. 9 depicts an example process flow for updating an association between two data units in accordance with various embodiments of the present disclosure;

FIG. 10 depicts an example process flow for deleting a data unit in accordance with various embodiments of the present disclosure;

FIG. 11 depicts an example process flow for deleting an association between a cue and a data unit in accordance with various embodiments of the present disclosure;

FIG. 12 depicts an example process flow for changing the parameters of a locality in accordance with various embodiments of the present disclosure;

FIG. 13 depicts an example process flow for updating the parameters and content of a data unit in accordance with various embodiments of the present disclosure;

FIG. 14 depicts an example process flow for fetching cue identifiers in accordance with various embodiments of the present disclosure;

FIG. 15 depicts an example process flow for modifying the content of a cue in accordance with various embodiments of the present disclosure;

FIG. 16 depicts an example process flow for updating an association between a cue and a data unit in accordance with various embodiments of the present disclosure;

FIG. 17 depicts an example process flow for transferring a data unit from one locality to another in accordance with various embodiments of the present disclosure;

FIG. 18 depicts an example process flow for changing the parameters of a hive in accordance with various embodiments of the present disclosure;

FIG. 19 depicts an example process flow for adding a new association between a data unit and a cue in accordance with various embodiments of the present disclosure;

FIG. 20 depicts an example process flow for adding a new cue to a hive in accordance with various embodiments of the present disclosure;

FIG. 21 depicts an example process flow for deleting a cue in a hive in accordance with various embodiments of the present disclosure;

FIGS. 22A, 22B, 22C, 22D, and 22E depict example simulations associated with embodiments of the present disclosure;

FIGS. 23A, 23B, 23C, 23D, and 23E depict example simulations associated with embodiments of the present disclosure;

FIGS. 24A, 24B, 24C, 24D, and 24E depict example simulations associated with embodiments of the present disclosure;

FIG. 25 illustrates visual examples of dynamism associated with embodiments of the present disclosure;

FIG. 26 illustrates a guided tag extraction method in accordance with at least some embodiments of the present disclosure;

FIG. 27A illustrates an initial data graph in accordance with at least some embodiments of the present disclosure; and

FIG. 27B illustrates an updated data graph in accordance with at least some embodiments of the present disclosure.

### DETAILED DESCRIPTION OF SOME EXAMPLE EMBODIMENTS

Various embodiments of the present disclosure now will be described more fully hereinafter with reference to the accompanying drawings, in which some, but not all embodiments of the disclosures are shown. Indeed, these disclosures may be embodied in many different forms and should not be construed as limited to the embodiments set forth herein; rather, these embodiments are provided so that this disclosure will satisfy applicable legal requirements. The term “or” (also designated as “/”) is used herein in both the alternative and conjunctive sense, unless otherwise indicated. The terms “illustrative” and “exemplary” are used to be examples with no indication of quality level. Like numbers refer to like elements throughout.

### Overview

Digital memory is an integral part of a computer system. It plays a major role in defining system performance. Memory access behavior largely depends on the nature of the incoming data and the specific information-processing tasks that operate on the data. Applications ranging from wildlife surveillance to infrastructure damage monitoring that collect, store and analyze data often exhibit distinct memory access (e.g., storage and retrieval of specific data blocks) behavior. Even within the same application, such behavior may change with time. Hence, these systems with variable and constantly evolving memory access pattern can benefit from a memory organization that can dynamically tailor itself to meet the requirements.

Furthermore, many applications deal with multi-modal data (e.g., image and sound) and in such applications, the data storage and access require special considerations in terms of their temporal importance and inter-modality relations. A data storage framework which can efficiently store and retrieve multi-modal data is crucial for these applications.

Many computing systems, specifically the emergent internet of things (IoT) edge devices, come with tight constraints on memory storage capacity, energy, and communication bandwidth. These systems often deal with a large influx of data with varying degree(s) of relevance to the application. Hence, storing and transmitting less useful data at higher quality may not be optimal. Due to these requirements, it is important for a memory framework to be efficient in terms of energy, space, and transmission bandwidth utilization by focusing on what is important for the specific application.

Based on these observations, an ideal data storage framework for these applications should be:
Flexible and dynamic in nature to accommodate for the constantly evolving application requirements and scenarios;
Able to emulate a virtually infinite memory that can deal with a huge influx of sensor data which is common in case of many IoT applications;
Able to efficiently handle multi-modal data in the context of the application-specific requirements; and
Geared towards increasing storage, transmission and energy utilization efficiency.

Traditional memory frameworks (both address-operated and content-operated) are not ideal for meeting these requirements due to lack of flexibility in their memory organization and operations. In an address-operated memory, each address is associated with a data unit. And for a content-operated memory, each data-search-pattern (cue/tag) is associated with a single data unit. Hence, in both cases, the mapping is one-to-one and does not evolve without direct admin/user interference. Data in a traditional memory is also stored at a fixed quality/granularity. When a traditional memory runs out of space, it can either stop accepting new data or remove old data based on a specific data replacement policy. All these traits of a traditional memory are tied to its static nature which makes it not suitable for modern applications that have evolving needs and requirements as established earlier.

For example, consider a wildlife image-based surveillance system which is geared towards detecting wolves. Any image frame that does not contain a wolf is considered to be of lower importance than any frame containing at least one wolf. However, a traditional memory, due to lack of dynamism in terms of data granularity management, will store the image frames at the same quality regardless of their importance to the application. Additionally, due to lack of dynamism in memory organization, searching for a wolf image will take the same effort/time as it would take for searching any rarely accessed and unimportant image.

To meet the requirements of many modern applications, it is attractive to incorporate flexibility and dynamism in the digital memory which can be best achieved through statistics-guided learning. Artificial Intelligence (AI) and Machine Learning (ML) can be used to solve different problems where static algorithms are not ideal. Similarly, meeting the dynamic memory requirements cannot be possible using static algorithms. Hence incorporation of intelligence may be an ideal solution for addressing current digital memory limitations.

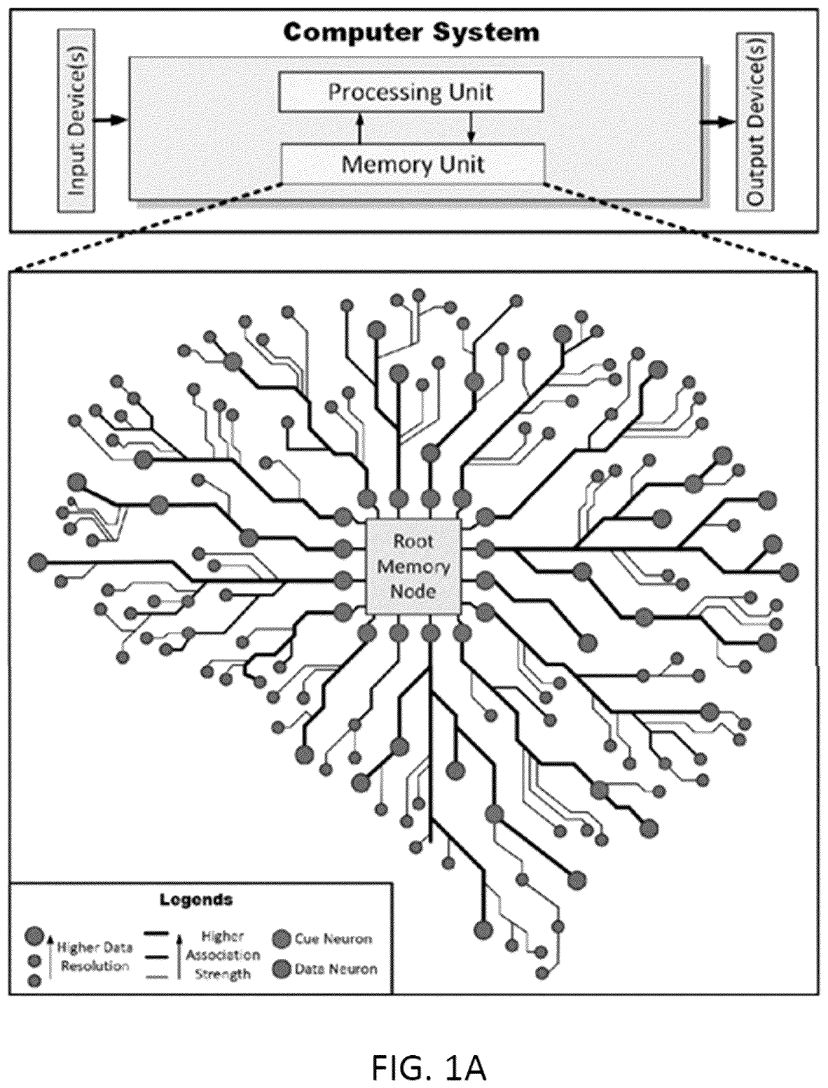

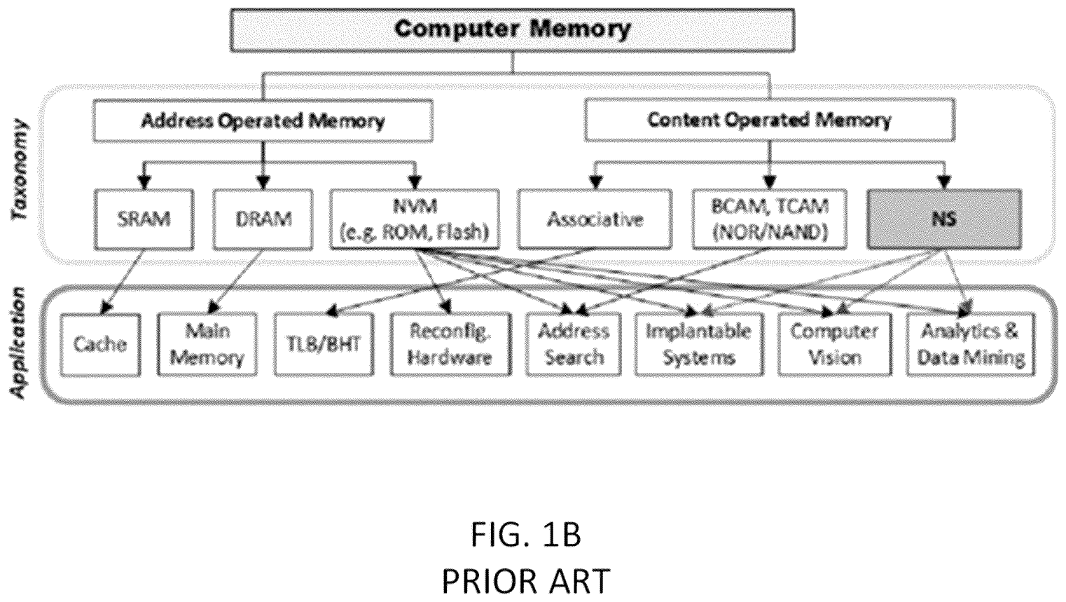

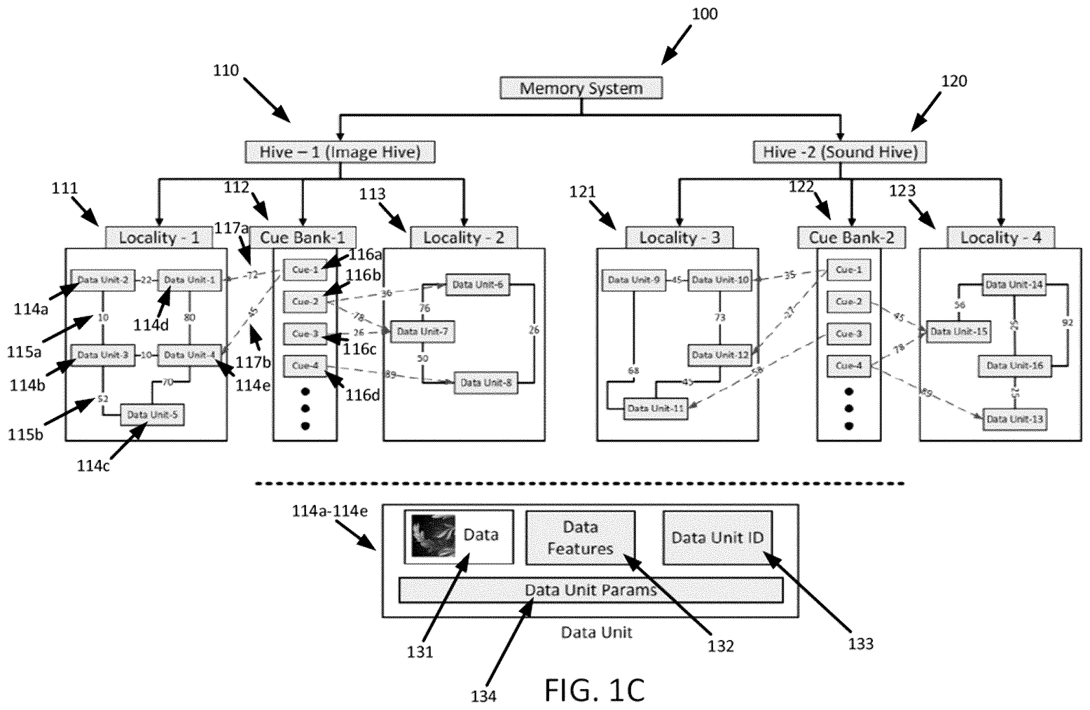

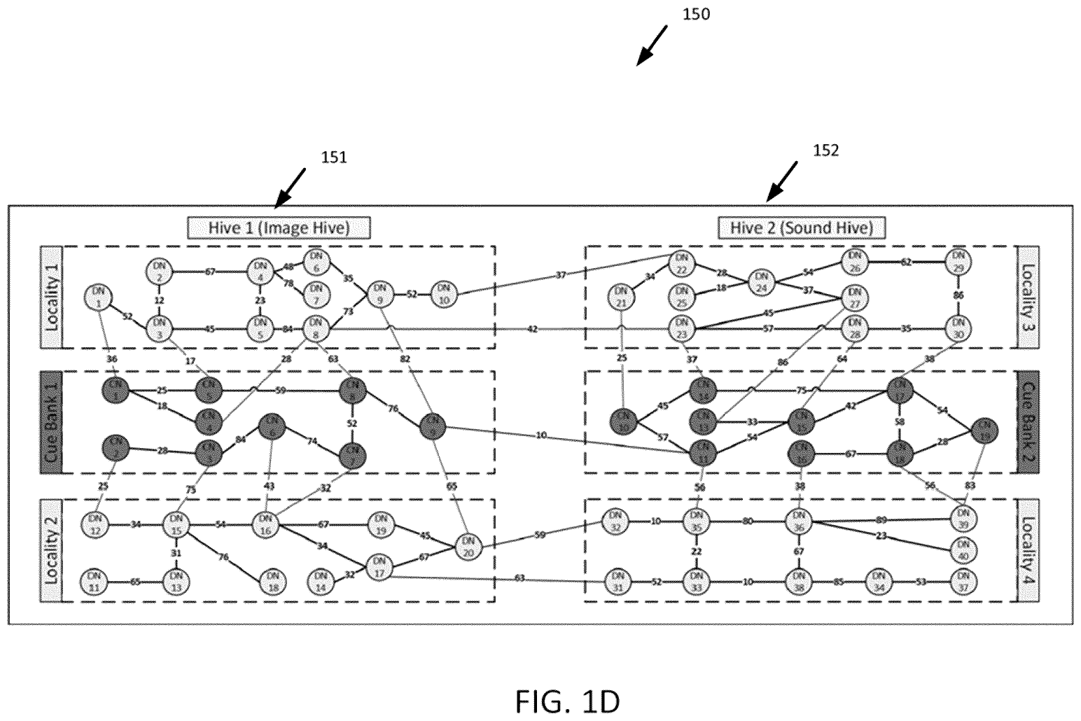

Embodiments herein enable a paradigm-shifting content-operated memory framework, sometimes referred to herein as learning-based storage (LS), which provides memory with ‘plasticity’ configured to adapt to present conditions, thereby enabling efficient storage and speedy access. In LS, the memory storage is a network of cues (search-patterns) and data, referred to herein as Neural Memory Network (NMN). Based on the feedback generated from each memory operation, reinforcement learning is used to (1) optimize the NMN data/cue organization and (2) adjust the granularity (feature quality) of specific data units. LS is designed to have the same interface as any traditional Content Addressable Memory (CAM). This allows LS to efficiently replace traditional CAMs in any application as shown in FIG. 1A. Applications which are resistant to imprecise data storage/retrieval and deals with storing data of varying importance will benefit the most from using LS.

For quantitatively analyzing the effectiveness of using LS as a memory system, an LS memory simulator with an array of tunable hyperparameters was used. Different real-life applications have been run on the memory simulator using LS and it has been observed that the LS framework utilizes orders of magnitude less space, and exhibits higher retrieval efficiency while incurring minimal impact on the application performance.

Table 1 provides an example comparison between embodiments herein (e.g., LS) and traditional memory frameworks. Observable from Table 1, embodiments herein have a dynamic nature, guided by continuous reinforcement learning, making them adaptable to application requirements and usage scenarios.

TABLE 1
Comparison of Embodiments Herein and Conventional Memory Frameworks

| | Dynamism | | | Associativity | | | |
|---|---|---|---|---|---|---|---|
| Memory | | Data | | <Cue, | <Date, | <Cue, | Space |
| Organization | Learning | Resolution | Association | Date> | Date> | Cue> | Efficiency |
| Address | N/A | Fixed | User | N/A | N/A | N/A | Low |
| Operated | | | defined | | | | |
| memory | | | | | | | |
| BCAM, | N/A | Fixed | User | One- | N/A | N/A | Low |
| TCAM, | | | defined | to- | | | |
| Associative | | | | One | | | |
| NS | Continuous | Changes | Changes | Many- | Many- | Many- | High |
| (Embodiments | | Based on | Based on | to- | to- | to- | |
| herein) | | Access | Access | Many | Many | Many | |
| | | Pattern | Pattern | | | | |

### Computer Memory: A Brief Review

Computer memory is a key component of a computer system. Different types of memory have been proposed, implemented and improved over the decades. However, digital memories can still be can be broadly divided into two categories based on how data is stored and retrieved: (1) address operated and (2) content operated. In an address operated memory (for example a Random Access Memory or RAM), the access during read/write is done based on a memory address/location. During data retrieval/load, the memory system takes in an address as input and returns the data associated with it. Different variants of RAM such as SRAM (Static Random Access Memory) and DRAM (Dynamic Random Access Memory) are widely used. In a content operated memory, on the contrary, memory access during read/write operations is performed based on a search pattern (e.g., content).

A COM (Content Operated Memory) does not assign any specific data to a specific address during the store operation. During data retrieval/load, the user provides the memory system with a search pattern/tag and the COM searches the entire memory and returns the address in the memory system where the required data is stored. This renders the search process extremely slow if performed sequentially. To speed up this process of content-based searching, parallelization is employed which generally requires additional hardware, which makes the COM a rather expensive solution limiting its large-scale usability. A COM can be implemented in several ways as shown in FIG. 1B, each with its own set of advantages and disadvantages. In an associative memory, the data are stored with a varying degree of restrictions.

In a direct-mapped memory, each data can only be placed in one specific memory location. The restriction is less stringent in case of set-associative memory and in-case of fully associative memory, any data can reside anywhere in the memory. On the other hand, Neuromorphic associative memory behaves in a similar way as the standard associate memory at a high level but at a low-level, it exploits device properties to implement neuronal behavior for increased efficiency. A CAM (Content-Addressable Memory) is similar to an associative memory in regard to its read and write behavior; however, the implementation of a CAM is different from the implementation of an associative memory. In COM, there is a requirement for replacing old data units with new incoming data units in-case the memory runs out of space. The data unit/block to replace is determined based on a predefined replacement policy. CAM is the most popular variant of COM and is being used for decades in the computing domain but the high-level architecture of a CAM has not evolved much. Instead, researchers have mostly focused on how to best physically design a CAM to improve overall efficiency. SRAM bitcells are used as a backbone for any CAM cell. Extra circuitry is introduced to perform the parallel comparison between the search pattern and the stored data. This is typically implemented using an XOR operation. The high degree of parallelism increases the circuit area and power overheads along with the cost. Cells implemented using NAND gates are more energy-efficient at a cost of speed. NOR gate-based cells are faster but more energy-intensive.

Traditional CAMs are designed to be precise. No data degradation happens over time and in most cases, a perfect match is required with respect to the search pattern/tag to qualify for a successful retrieval. This feature is essential for certain applications such as destination MAC address lookup for finding the forwarding port in a network device. However, there are several applications in implantable, multimedia, Internet-of-Things (IoT) and data mining which can tolerant imprecise storage and retrieval. Ternary Content Addressable Memory (TCAM) is the only COM which allows partial match using a mask and are widely used in layer 3 network switches.

While embodiments herein may include a content operated memory framework, there are several differences between a traditional CAM and embodiments herein (e.g., some highlighted in Table 1). For both Binary Content Addressable Memory (BCAM) and Ternary Content Addressable Memory (TCAM): (1) there are no learning components, (2) data resolution remains fixed unless directly manipulated by the user, (3) associations between search-pattern (tag/cue) and data remain static unless directly modified, (4) only a one-to-one mapping relation exists between search-pattern/cue and data units. Consequently, space and data fetch efficiency is generally low.

Apart from standard computer memory organizations, researchers have also looked into different software level memory organizations for efficient data storage and retrieval. Instance retrieval frameworks are some such software wrappers on top of traditional memory systems that are used for feature-based data storage and retrieval tasks. These systems are mostly used for storing and retrieving images. During the training phase (code-book generation), visual words are identified/learned based on either SIFT features or CNN features of a set of image data. These visual words are, in most cases, cluster centroids of the feature distribution. Insertion of data in the system follows and is generally organized in a treelike data structure. The location of each data in this data structure is determined based on the visual words (previously learned) that exist in the input image. During the retrieval phase, a search-image is provided and in an attempt to search for similar data in the framework, the tree is traversed based on the visual words in the search image. If a good match exists between the search image and a stored image, then that specific stored image is retrieved. The learning component in an instance retrieval frameworks is limited to the code-book generation phase which takes place during initialization. Furthermore, once a data unit is inserted in the framework, no more location and accessibility change is possible. No association exists between data units and granularity of data units do not change. On contrary, the overall dynamism and possibilities of a framework according to embodiments herein are much more.

Another software level memory organization outlines the benefit of forgetfulness in a digital memory. However, due to the lack of quantitative analysis and implementation details, it is unclear how effective this framework might be.

### Improved Memory Features

Computer memory is designed to perform data storage, retention and retrieval. The following memory system properties, when realized in a digital computer memory, offer benefits to many applications.

### Virtually Infinite Capacity:

Embodiments of digital memory as described herein are configured to re-organize data dynamically and intelligently, thereby providing learning-guided plasticity of the system. Embodiments of digital memory systems as described herein are configured to prune features of unnecessary data based at least in part on insights learned from statistical feedback, thereby enabling considerably increased capacity. For example, in a wildlife image-based surveillance system which is geared towards detecting wolves, the irrelevant data (non-wolf frames) can be subject to compression/feature-loss to save space without hampering the effectiveness of the application.

Imprecise/Imperfect Storage and Access: Embodiments of digital memory systems as described herein prune unnecessary data based at least in part on intelligent feature extraction, analysis, and post-processing. Further yet, certain tasks may not require precise memory storage and recall. For these tasks only some high-level feature extracted from the raw data is sufficient, and as such, digital memory systems as described herein may be configured to prune considerable amounts of raw data subsequent to the extraction of the subject high-level feature, thereby enabling attaining increased capacity and faster data access.

For example, a wildlife image-based surveillance system can operate in the imprecise domain because some degree of compression/feature-reduction of images will not completely destroy the high-level features necessary for its detection tasks. This can lead to higher storage and transmission efficiency.

Dynamic Organization: Plasticity also provides several other benefits in the digital memory domain. Plasticity has been defined as a memory's capacity to respond to experienced demands with structural changes that alter the behavioral. Hence plasticity leads to better accessibility of important and task-relevant data. Further, the case-of-access of a particular memory item is adjusted with time-based on a system's requirements, thereby enabling quicker retrieval.

Embodiments herein provide for a digital memory which can re-organize itself based on data access patterns and statistical feedback, enabling great benefits in terms of reducing the overall memory access effort. For example, a wildlife image-based surveillance system which is geared towards detecting wolves will have to deal with retrieval requests mostly related to frames containing wolves. Dynamically adjusting the memory organization can enable faster access to data which are requested the most.

Learning Guided Memory Framework: Depending on the need and requirement of a particular digital memory system, certain data are prioritized over others. The process of organizing the memories, feature reduction, storage and retrieval procedure changes over time based on statistical feedback. Incorporation of a learning component in a plurality of digital memory systems enables each digital memory system to be tuned to excel at a particular task at a particular time.

Using this learning component, the digital memory will re-organize itself over time and alter the granularity of the data to become increasingly efficient (in terms of storage, retention and retrieval) at a particular task. For example, a wildlife image-based surveillance system which is geared towards detecting wolves will greatly benefit from a memory system which can learn to continuously re-organize itself to enable faster access to application-relevant data and continuously control the granularity of the stored data depending on the evolving usage scenario.

Accordingly, embodiments herein incorporate dynamism and embody the desirable qualities of a digital memory as described. Embodiments herein include an intelligent, self-organizing, virtually infinite content addressable memory framework capable of dynamically modulating data granularity. Memory architectures herein couple with processes for implementing operations/tasks such as store, retrieve and retention enable the aforementioned technological improvements and more.

### Computer Program Products, Systems, Methods, and Computing Entities

Embodiments of the present disclosure may be implemented in various ways, including as computer program products that comprise articles of manufacture. Such computer program products may include one or more software components including, for example, software objects, methods, data structures, and/or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages include, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form. A software component may be stored as a file or other data storage construct. Software components of a similar type or functionally related may be stored together such as, for example, in a particular directory, folder, or library. Software components may be static (e.g., pre-established or fixed) or dynamic (e.g., created or modified at the time of execution).

A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid-state drive (SSD), solid state card (SSC), solid state module (SSM), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may also be implemented as methods, apparatus, systems, computing devices, computing entities, and/or the like. As such, embodiments of the present disclosure may take the form of a data structure, apparatus, system, computing device, computing entity, and/or the like executing instructions stored on a computer-readable storage medium to perform certain steps or operations. Thus, embodiments of the present disclosure may also take the form of an entirely hardware embodiment, an entirely computer program product embodiment, and/or an embodiment that comprises combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some exemplary embodiments, retrieval, loading, and/or execution may be performed in parallel such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

### Exemplary Computer System Memory Framework

FIG. 1C provides an illustration of a computer system memory architecture 100 in accordance with various embodiments of the disclosure. The architecture 100 includes one or more memory hives 110, 120 that are responsible for storing data of a particular modality. Each memory hive 110, 120 represents a memory subsystem component that holds data of a certain type. For example, the architecture 100 can be designed to include a memory hive for image data 110 and another memory hive for sound data 120.

In addition, in various embodiments, each memory hive 110, 120 includes one or more localities 111, 113, 121, 123 that serve as regions within the hives 110, 120 for storing data units 114a-114e that hold data related to similar concepts. Accordingly, in particular embodiments, only a certain type of data may be stored in a specific locality 111, 113, 121, 123 as decided by the memory hive 110, 120. This concept enables similar memories to be grouped together to allow for faster access and increased retention. Accordingly, when new data is stored in the memory system 100, the new data is assigned to a locality 111, 113, 121, 123 based on certain features of the new data. Here, a mapping between data features and the different localities 111, 113, 121, 123 may be used in assigning data to the localities 111, 113, 121, 123. This mapping may be user defined or learned by the system 100 over time based on data access patterns, salience, and/or other parameters. Further, different localities 111, 113, 121, 123 can have different retention ability and search priorities.

In various embodiments, each of the data unit 114a-114e contains a data element 131, data features 132, an identifier 133, and one or more data unit parameters 134. In addition, the data units 114a-114e stored in each locality 111, 113, 121, 123 are interconnected (e.g., weighted) 115a-115b based on relationships with each other. These interconnections 115a-115b can be used during data retrieval to increase access. In some embodiments, the interconnections 115a-115b between data units 114a-114e can change depending on the state of the memory system 100. One attribute of a data unit 114a-114e may be its memory strength and/or presence. Here, the strength determines the retention quality of the data unit 114a-114e and its accessibility. Accordingly, in particular embodiments, the strength of each data unit 114a-114e may decay with time at a rate determined by a user or via statistical learning. While data unit strength may increase when a data unit 114a-114e is accessed or is merged with another data unit 114a-114e. In addition, the memory system 100 in particular embodiments may be configured to move data units 114a-114e to different localities 111, 113, 121, 123 depending on the system state and external stimulus.

The memory system 100 also includes one or more cue banks 112, 122 in various embodiment used to store cues for various memory hives 110, 120. Each memory hive 110 is typically associated with a cue bank 112 where several cues 116a-116d are stored. A cue 116a-116d is a multi-modal element that can be semantically linked 117a-117b with several data units 114d-114e within the respective memory hive 110. New cues 116a-116d can be generated during the lifecycle of the memory system 100 and sometimes cues 116a-116d may get deleted as well depending on external stimulus. In addition, the strength of different cue-to-data-unit associations 117a-117b can be dynamically adjusted during the lifecycle of the memory system 100.

Accordingly, the memory system 100 may be initialized in various embodiments based on one or more defined parameters. In particular embodiments, the parameters may be changed during operation cither manually by a user and/or automatically based on statistical information and/or learning. For instance, one or more of the following parameters may be defined and used: number of localities; priorities of each locality; memory strength decay rate associated with each locality; mapping between data features and locality; data feature extraction models to use in which online learning can be enabled to allow the models to learn during operation; cue extraction artificial intelligence (AI) models in which online learning can be enabled to allow the models to learn during operation; data unit merging threshold; elasticity parameters; data unit locality transfer parameters; data unit interconnection topology and driving parameters; selective in-memory inferencing guiding parameters; and precise and imprecise memory split parameters.

FIG. ID depicts an illustration of a neural memory network (NMN) 150 in accordance with various embodiments of the disclosure. In FIG. 1D, the NMN 150 consists of multiple hives (e.g., 151, 152) each of which may be used to store data of a specific modality (e.g., type; image, sound). For example, if an application requires to store image and audio data, then frameworks according to embodiments herein instantiate two separate memory hives-one for each data modality. This allows the search to be more directed based on the query data type In at least some embodiments, the NMN 150 creates small memory localities within each hive that are designed to store similar data.

In embodiments, units of the NMN 150 may include (1) cue objects and (2) data objects. Each cue unit stores a cue (data search pattern or tag) and each data object stores an actual data unit. Each data object is associated with a number denoting its memory strength which governs the data feature details or quality of the data inside it. A cue is a vector representing a certain concept and it can be of two types: (1) Coarse-grained cue and (2) Fine-grained Cue. Coarse-grained cues are used to navigate the NMN efficiently while searching (data retrieve operation) for a specific data and while navigating. The fine-grained cues are used to determine the data object(s) which is/are suitable for retrieval. It will be appreciated that, while a cue is a vector representing a particular concept, specific words are used herein (without limitation) when referring to certain cues. For example, in a wildlife surveillance system, cue objects may contain vectors corresponding to a “Wolf,” “Deer,” or the like. However, when referring to these cue-units, the present disclosure may refer to them directly with the name of the concept they represent. The data objects, for this example, may be image frames containing wolves, deer, jungle background, etc. Furthermore, if the system is designed to detect wolves, then embodiments herein can be configured to have a memory locality for wolf-frames and one for non-wolf frames.

Each hive may have its own cue bank which stores cue objects arranged as a graph. The cue object and data object associations (<cue object, cue object> and <cue object, data object>, <data object, data object>) change with time, based on the memory access pattern and framework hyperparameters. To facilitate multi-modal data search, connections between data objects across memory hives are allowed. For example when searched with the cue “Wolf” (the visual feature of a wolf), if the system is expected to fetch both images and sound data related to the concept of “Wolf”, then this above-mentioned flexibility will save search effort.

It will be appreciated that the entire memory organization can be viewed as a single weighted graph where each node is either a data object or a cue object. The associations in the NMN 150 are strengthened and weakened during store, retrieve and retention operations. With time, new associations are also formed and old associations may get deleted. The data object memory strengths are also modulated during memory operations to increase storage efficiency. The rigidity provided by hives, localities and cue-banks can be adjusted based on the application requirements.

### Exemplary Computing Entity

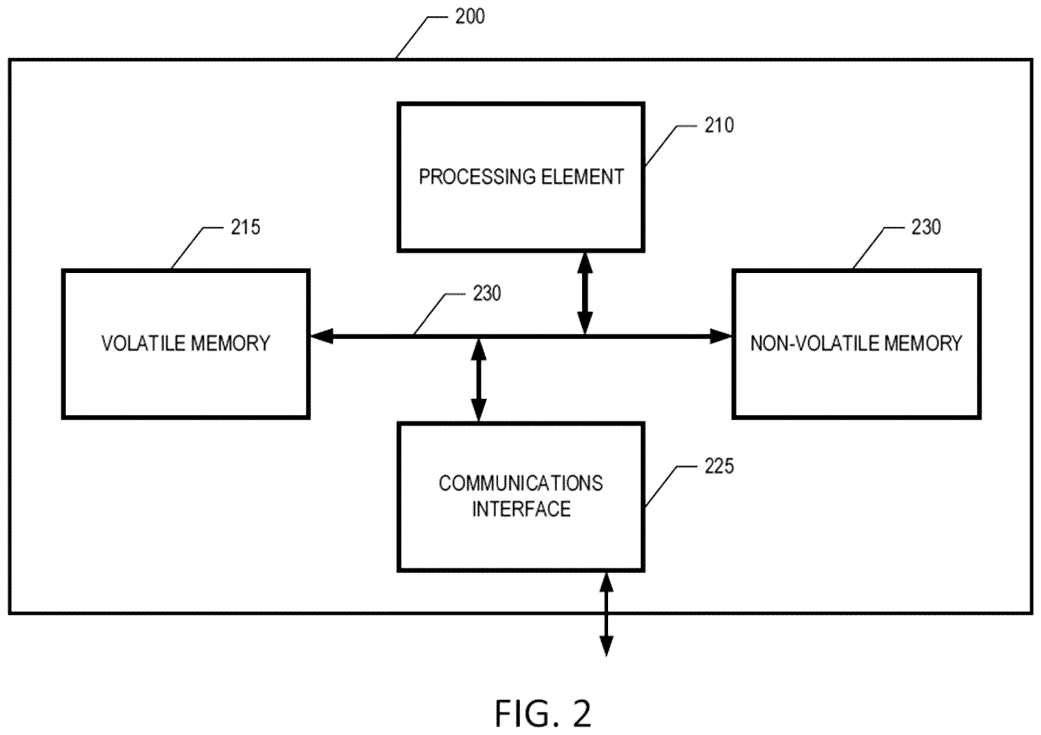

FIG. 2 provides a schematic of a computing entity 200 that may make use of the memory system 100 according to various embodiments of the present disclosure. In general, the terms computing entity, entity, device, system, and/or similar words used herein interchangeably may refer to, for example, one or more computers, computing entities, desktop computers, mobile phones, tablets, phablets, notebooks, laptops, distributed systems, items/devices, terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

Although illustrated as a single computing entity, those of ordinary skill in the art should appreciate that the computing entity 200 shown in FIG. 2 may be embodied as a plurality of computing entities, tools, and/or the like operating collectively to perform one or more processes, methods, and/or steps. As just one non-limiting example, the computing entity 200 may comprise a plurality of individual data tools, each of which may perform specified tasks and/or processes.

Depending on the embodiment, the computing entity 200 may include one or more network and/or communications interfaces 225 for communicating with various computing entities, such as by communicating data, content, information, and/or similar terms used herein interchangeably that can be transmitted, received, operated on, processed, displayed, stored, and/or the like. Thus, in certain embodiments, the computing entity 200 may be configured to receive data from one or more data sources and/or devices as well as receive data indicative of stakeholder input, for example, from a device.

The networks used for communicating may include, but are not limited to, any one or a combination of different types of suitable communications networks such as, for example, cable networks, public networks (e.g., the Internet), private networks (e.g., frame-relay networks), wireless networks, cellular networks, telephone networks (e.g., a public switched telephone network), or any other suitable private and/or public networks. Further, the networks may have any suitable communication range associated therewith and may include, for example, global networks (e.g., the Internet), MANs, WANs, LANs, or PANs. In addition, the networks may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, satellite communication mediums, or any combination thereof, as well as a variety of network devices and computing platforms provided by network providers or other entities.

Accordingly, such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. Similarly, the computing entity 200 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1X (1xRTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol. The computing entity 200 may use such protocols and standards to communicate using Border Gateway Protocol (BGP), Dynamic Host Configuration Protocol (DHCP), Domain Name System (DNS), File Transfer Protocol (FTP), Hypertext Transfer Protocol (HTTP), HTTP over TLS/SSL/Secure, Internet Message Access Protocol (IMAP), Network Time Protocol (NTP), Simple Mail Transfer Protocol (SMTP), Telnet, Transport Layer Security (TLS), Secure Sockets Layer (SSL), Internet Protocol (IP), Transmission Control Protocol (TCP), User Datagram Protocol (UDP), Datagram Congestion Control Protocol (DCCP), Stream Control Transmission Protocol (SCTP), HyperText Markup Language (HTML), and/or the like.

In addition, in various embodiments, the computing entity 200 includes or is in communication with one or more processing elements 210 (also referred to as processors, processing circuitry, and/or similar terms used herein interchangeably) that communicate with other elements within the computing entity 200 via a bus 230, for example, or network connection. As will be understood, the processing element 210 may be embodied in several different ways. For example, the processing element 210 may be embodied as one or more complex programmable logic devices (CPLDs), microprocessors, multi-core processors, coprocessing entities, application-specific instruction-set processors (ASIPs), and/or controllers. Further, the processing element 210 may be embodied as one or more other processing devices or circuitry. The term circuitry may refer to an entirely hardware embodiment or a combination of hardware and computer program products. Thus, the processing element 210 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processing element 210 may be configured for a particular use or configured to execute instructions stored in volatile or non-volatile media or otherwise accessible to the processing element 210. As such, whether configured by hardware, computer program products, or a combination thereof, the processing element 210 may be capable of performing steps or operations according to embodiments of the present disclosure when configured accordingly.

In various embodiments, the computing entity 200 may include or be in communication with non-volatile media (also referred to as non-volatile storage, memory, memory storage, memory circuitry and/or similar terms used herein interchangeably). Accordingly, the non-volatile media may be configured in accordance with various embodiments of the memory system 100 disclosed herein. The memory according to various embodiments can be integrated into any computer system and implemented with any memory technology, including NVM (e.g., flash) or volatile memory (e.g., SRAM or DRAM array). Moreover, it can be used as a stand-alone memory device that interfaces with a central processing unit (e.g., a processor, or graphics processing unit, or Field Programmable Gate Array); or a memory unit integrated with a processor in the same chip. While the physical implementation of the proposed memory can be done with existing memory technologies, its organization and access behavior, as well as data retention and update behavior are distinct from traditional computer memory. The non-volatile storage or memory may include one or more non-volatile storage or memory media 220 such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or memory media 220 may store data such as files, databases, database instances, database management system entities, images, applications, programs, program modules, scripts, source code, object code, byte code, compiled code, interpreted code, machine code, executable instructions, and/or the like. The term database, database instance, database management system entity, and/or similar terms used herein interchangeably and in a general sense to refer to a structured or unstructured collection of information that is stored in a computer-readable storage medium.

In particular embodiments, the memory media 220 may also be embodied as a data storage device or devices, as a separate database server or servers, or as a combination of data storage devices and separate database servers. Further, in some embodiments, the memory media 220 may be embodied as a distributed repository such that some of the stored information/data is stored centrally in a location and other information/data is stored in one or more remote locations. Alternatively, in some embodiments, the distributed repository may be distributed over a plurality of remote storage locations only.

In various embodiments, the computing entity 200 may further include or be in communication with volatile media (also referred to as volatile storage, memory, memory storage, memory circuitry and/or similar terms used herein interchangeably). For instance, the volatile storage or memory may also include one or more volatile storage or memory media 215 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. As will be recognized, the volatile storage or memory media 215 may be used to store at least portions of the databases, database instances, database management system entities, data, images, applications, programs, program modules, scripts, source code, object code, byte code, compiled code, interpreted code, machine code, executable instructions, and/or the like being executed by, for example, the processing element 210. Thus, the databases, database instances, database management system entities, data, images, applications, programs, program modules, scripts, source code, object code, byte code, compiled code, interpreted code, machine code, executable instructions, and/or the like may be used to control certain aspects of the operation of the computing entity 200 with the assistance of the processing element 210 and operating system.

As will be appreciated, one or more of the computing entity's components may be located remotely from other computing entity components, such as in a distributed system. Furthermore, one or more of the components may be aggregated and additional components performing functions described herein may be included in the computing entity 200. Thus, the computing entity 200 can be adapted to accommodate a variety of needs and circumstances.

### Exemplary System Operations

### Properties of Various Embodiments

As previously noted, various embodiments of the memory system 100 provide a plurality of desirable qualities. Accordingly, many of these properties are implemented in various embodiments by the process flow previously discussed.

Embodiments of the memory system 100 provide selective in-memory inferencing by enabling portions of any memory operation to be scheduled for in-memory processing.

Embodiments of the memory system 100 provide both precise and imprecise memory options by providing mechanisms such as hive and locality parameters via which preciseness can be controlled.

In at least some embodiments, the memory system enables cue and feature driven memory storage and retrieval by using one or more AI models to extract and use features and cues for operations such as data retrieval, data storage, data retention, and data update tasks.

Embodiments of the memory system 100 provide in-memory associations and cue based retrieval by associating data units with one another inside localities.

In at least some embodiments, cues can be associated with multiple data units, thereby enabling faster fetch time.

Embodiments of the memory system 100 provide memory strength decay by diminishing the strength of data units if they have not been re-enforced.

In at least some embodiments, the memory system 100 provides retrieval and data unit merging, thereby providing memory re-enforcing, memory strength, and accessibility increases.

Embodiments of the memory system 100 provide memory spatial distribution by structuring the localities with soft boundaries between data units representing different memory clusters.

In at least some embodiments, the memory system 100 expands storage capabilities by using memory elasticity during data storage.

Embodiments of the memory system 100 allow inter-data unit connectivity graphs to change during data retrieval, data storage, data retention, and data update tasks, thereby providing memory plasticity.

In at least some embodiments, memory system 100 supports a high degree of parallelization.

Embodiments of the memory system 100 enable statistical reinforcement learning to dictate different memory operations.

### Parameters

Several parameters are used within embodiments herein to help modulate how the embodiments function. For example, these parameters may be of two types: (1) Learnable Parameters which changes throughout the system lifetime guided by reinforcement-learning; and (2) Hyperparameters which are determined during system initialization and changed infrequently by the memory user/admin.

### Learnable Parameters

The following may be considered learnable parameters according to embodiments herein.

Data Object and Cue Object Weighted Graph: The weighted graph (NMN) directly impacts the data search efficiency (time and energy). The elements of the graph adjacency matrix are considered as learnable parameters. If there are D number of data objects and C number of cue objects at any given point of time, then the graph adjacency matrix will be of dimension (D+C, D+C).

Memory Strength Array: The memory strengths of all the data objects are also considered as learnable parameters. They jointly dictate the space-utilization, transmission efficiency and retrieved data quality.

These parameters constantly evolve based on the system usage via a reinforcement learning process.

### Hyperparameters

A set of hyperparameters is also provided herein which influences the LS memory organization and the learning guided operations. These hyperparameters can be set/changed by the user during the setup or during the operational stage. The first hyperparameter is the number of memory hives the following hyperparameters may be associated with each hive (e.g., each hive may have one or more of the following hyperparameters).

Number of localities: Each locality is used to store a specific nature of data. It may be an unsigned integer value. If there exist X types of objects-of-interest for an application, then using X+1 localities is advised. Every object-type can be assigned to a specific locality for optimal search efficiency and data granularity control. The last locality can be used for storing the unimportant data.

Memory decay rate of each locality: Controls the rate at which data object memory strength and features are lost due to inactivity. It may be a list (of length Lₙ) containing positive floating-point values. Assume that two localities L1 and L2 store separate object-types having importance I1 and I2 respectively. If I1>I2, then it is advised to pick the decay rate of L1 to be less than the decay rate of L2.

Association decay rate of each locality: Controls the rate at which NMN associations losses strength due to inactivity. It may be a list (of length Lₙ) containing positive floating-point values. Assume that two localities L1 and L2 store separate object-types having importance I1 and I2 respectively. If I1>I2, then it is advised to pick the decay rate of L1 to be less than the decay rate of L2.

Mapping between data features and localities: This mapping dictates the segregation of application relevant data and their assignment to a locality with a low decay rate. It may be a dictionary with Lₙ entries (one for each locality). Each entry is a list of data features (vectors) which when present in a data makes it a fit for the respective locality.

Data features and cue extraction AI (Artificial Intelligence) models: These models are used to obtain more insights about the data. They may be selected based on the application and data-type being processed.

Data object matching metric: Used during retrieve operation for finding a good match and during store operation for data object merging. For example, this metric can be something like cosine similarity.

Elasticity parameters: Determines the aggressiveness with which unused data objects are compressed in-case of space shortage. It may be a dictionary with Lₙ entries. Each entry (corresponding to each locality) is a list of positive floating-point values. The values indicate the amount of memory strength loss imposed in successive iterations of the elasticity procedure.

Association weight adjustment parameter: Used as a step size for increasing/decreasing association weights inside the NMN. A higher value will increase the dynamism but lower the stability.

Minimum association weight (i): An unsigned integer which limits the decay of association weight beyond a certain point. A lower value may increase dynamism.

Degree of impreciseness (φ): Limits the amount of data feature which is allowed to be lost due to memory strength decay and inactivity. It may be a floating-point number in the range [0-100]. 0 implies data can get completely removed if needs arise. Keeping the parameter at 1 may ensure everything remains in the memory while retaining some unimportant memories at extremely low quality.

Frequency of retention procedure (N): LS has a retention procedure which brings in the effect of ageing. This hyperparameter may be a positive integer denoting the number of normal operations to be performed before the retention procedure is called once. A lower value will increase dynamism at a cost of overall operation effort (energy and time consumption).

Compression techniques: For each memory hive, the algorithm to be used for compressing the data when required. For example, JPEG compression may be used in an image hive.

### Learning

The learnable parameters, governing the NMN (e.g., 150) of various embodiments herein are updated based on feedback from memory operations. Some objectives of learning include:
Reduce space requirement while maintaining data retrieval quality and application performance. This may be achieved by learning the granularity at which each data object should be stored. Less important data may be compressed and subject to feature-loss for saving space while more important data may be kept at a good quality. Hence this learning may be driven based on the access-pattern.
Increase memory search speed by learning the right NMN organization given current circumstances and access-pattern bias.

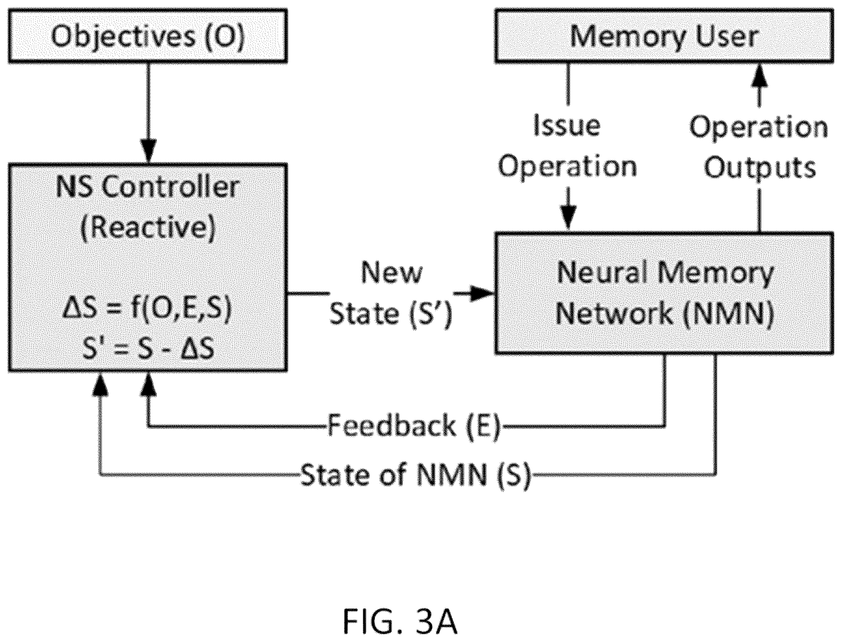

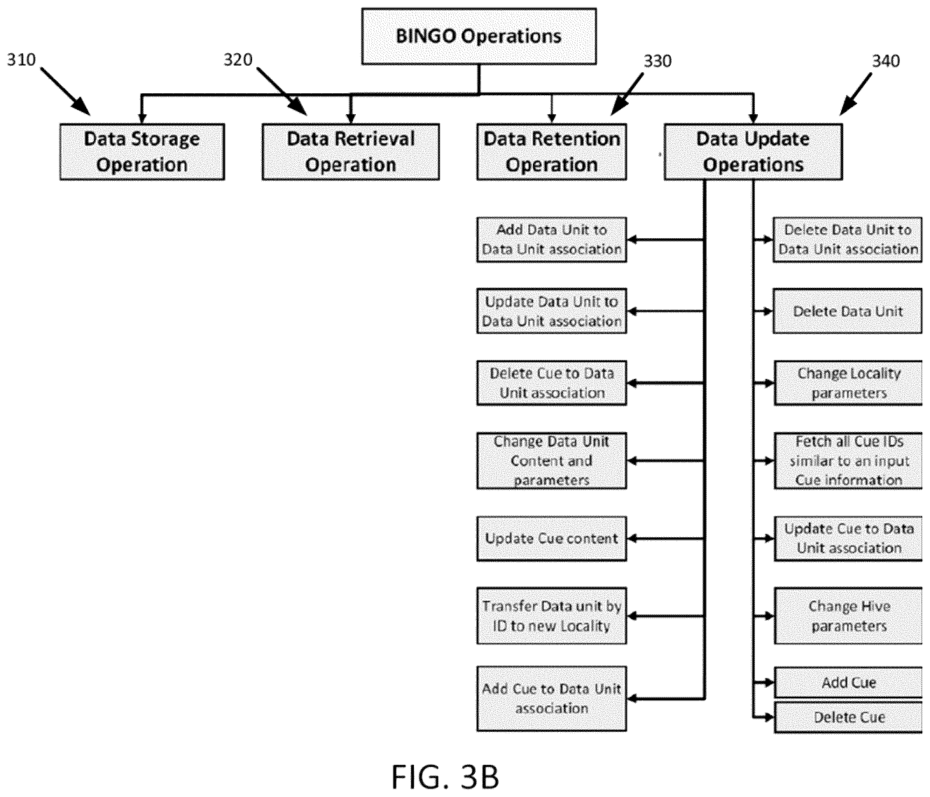

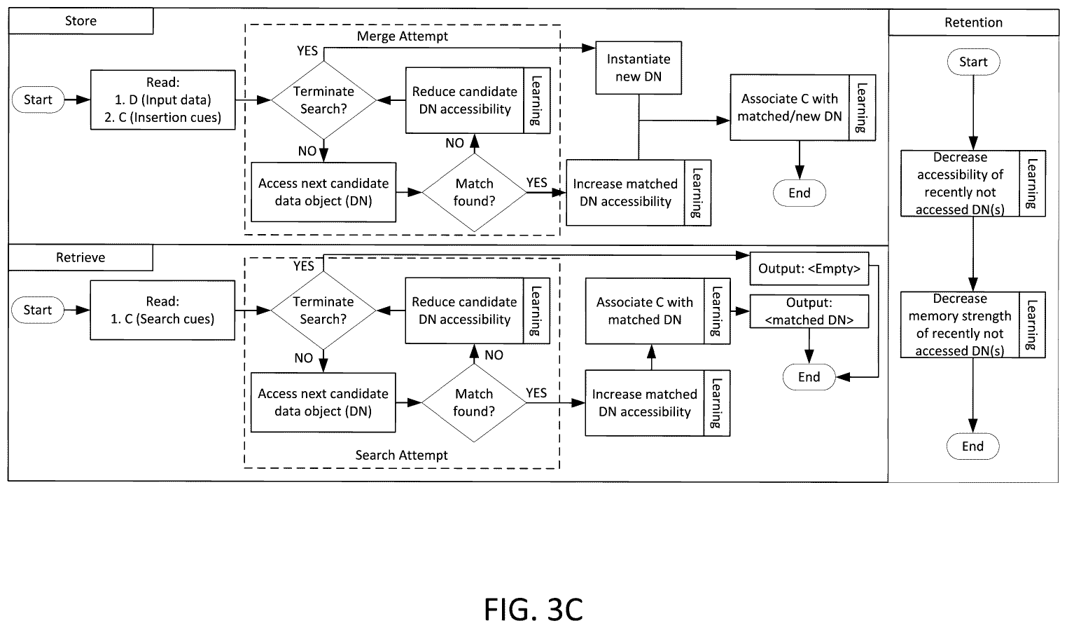

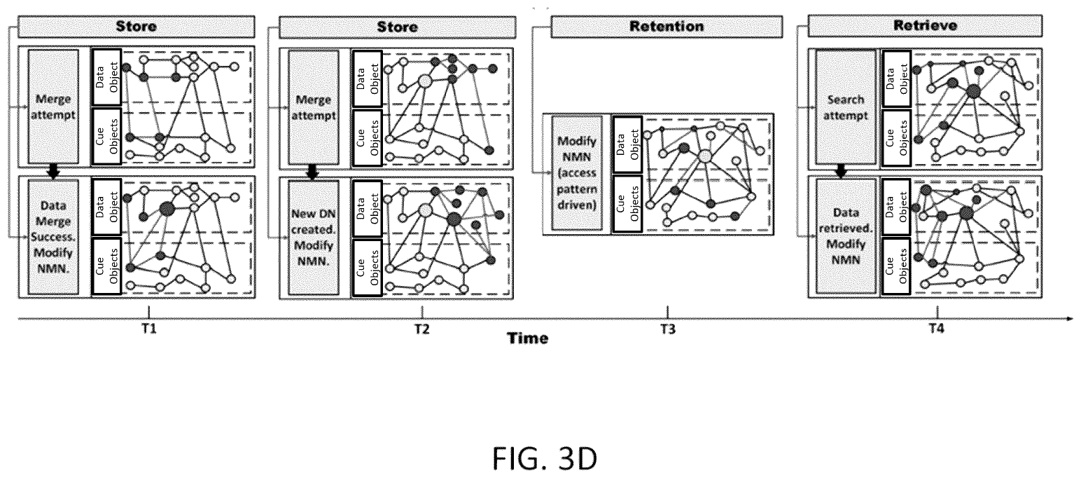

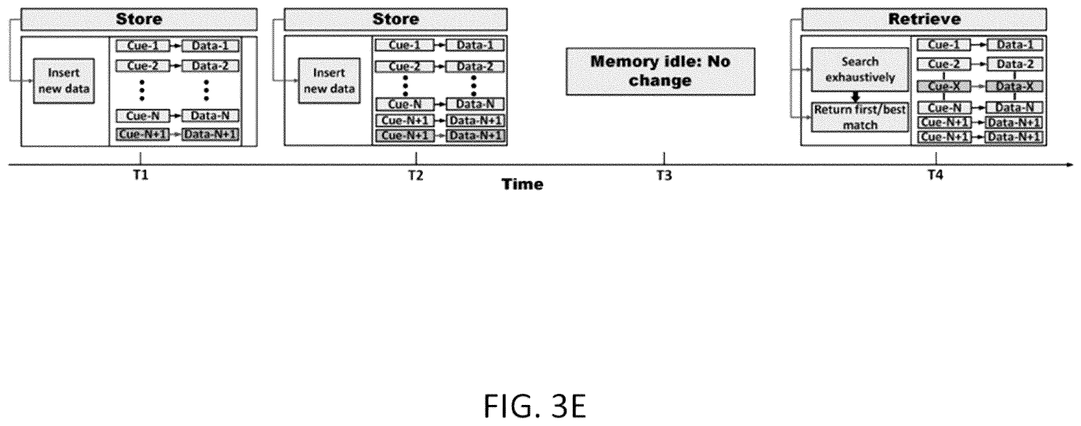

In FIG. 3A, an example external stimulus guided reactional reinforcement learning (RL) architecture for incorporating intelligence is depicted, according to embodiments herein. Embodiments herein may include an architecture or framework with two components: (1) a Neural Memory Network (NMN), and (2) an LS Controller which manages the NMN.

The initial state (S₀) of the NMN consists of no data-object (DN) and no cue-object (CN). During an operation when a new cue is identified (not present in the cue bank), a new cue-object (CN) is generated for that cue. Similarly, when an incoming data cannot be merged with an existing data-object (DN), a new DN is created. Each new DN is initialized with a memory strength of 100% (this parameter dictates the data granularity/details for the DN). When a new DN or CN is created, the new object is connected with all other existing objects (DNs and CNs) with an association weight of E (a hyperparameter selected by the system admin/user). Thus in any state, all DNs and CNs form a fully connected weighted graph.

At the end of each operation, a feedback (E) is generated and sent to the LS Controller module along with the snap shot of the current state of the NMN(S). S (e.g., the Learnable Parameters) may have two components:
S→A: The adjacency matrix for the entire NMN.
S→M: The list of memory strengths of each data object.

For an NMN with n total objects (DNs and CNs) and m number of DNs:

S and E, along with the learning goals/objectives (0) drives the reaction function f(O, E, S). The outputs of this function are:
An association weight adjustment matrix (ΔA) of dimension (n, n).
A memory strength adjustment vector ΔM) of dimension (1, m).

These 2 components constitute ΔS={ΔA, ΔM}.

$$Δ A = [ \vert \begin{matrix}δ {a}_{11} & δ {a}_{12} & δ {a}_{13} & … & δ {a}_{1 n} \\ δ {a}_{21} & δ {a}_{22} & δ {a}_{23} & … & δ {a}_{2 n} \\ … & … & … & … & … \\ δ {a}_{n 1} & δ {a}_{n 2} & δ {a}_{n 3} & … & δ {a}_{n n}\end{matrix} \vert ]$$

$$Δ M = [ \vert δ {s}_{1} δ {s}_{2} δ {s}_{3} δ {s}_{4} δ {s}_{5} … δ {s}_{m} \vert ]$$

S′ may be computed as follows:

$${S}^{′} \to A = [ \vert \begin{matrix}max ( ε , {a}_{11 -} δ {a}_{11} & … & max ( ε , {a}_{1 n -} δ {a}_{1 n} \\ max ( ε , {a}_{21 -} δ {a}_{21} & … & max ( ε , {a}_{2 n -} δ {a}_{a 21} \\ … & & … \\ max ( ε , {a}_{n 1 -} δ {a}_{n 1} & … & max ( ε , {a}_{nn -} δ {a}_{n 1}\end{matrix} \vert ]$$

$${S}^{′} \to M = [ \vert \begin{matrix}min ( 100 , max ( φ , {s}_{1 -} δ {s}_{1} ) ) \\ min ( 100 , max ( φ , {s}_{2 -} δ {s}_{2} ) ) \\ … \\ min ( 100 , max ( φ , {s}_{m -} δ {s}_{m} ) )\end{matrix} \vert ]$$

Where, φ (degree of impreciseness, a hyperparameter selected by the system admin/user) is the minimum memory strength a data object can have.

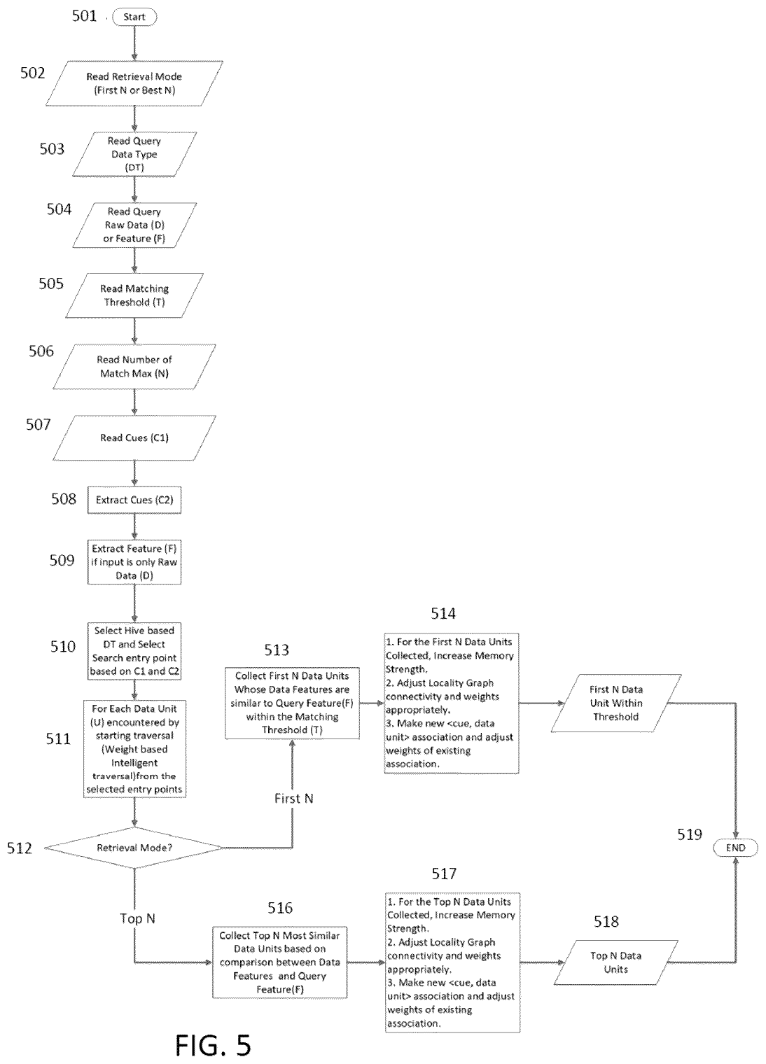

The memory state is updated with the newly computed one (S′). The function f(O, E, S) for computing ΔM and ΔA can be realized in many different ways depending on the implementation. The updates made to the matrices for a given state, S can be made local in nature to reduce unnecessary computations and updates. The periodicity of the state update can also be controlled. For various embodiments used for performing evaluations, the reaction function may be jointly implemented using one or more of Algorithm 1, Algorithm 2, and/or Algorithm 4. The algorithms are discussed in the Appendix, and the high level concept is provided in Fig. 5(a).

In various embodiments, four types of operations may be associated with the memory system 100 as shown in FIG. 3B: data storage 310; data retrieval 320; data retention 330; and update operations 340. Each of these types of operations 310, 320, 330, 340 is described further herein.

It is noted that many of these operations can be performed using various processing configurations depending on the embodiment. For example, the relevant content can be retrieved and used by the processing element 210 of a computing entity 200 for performing an update. While in other instances, a portion or the complete processing can be carried out in-memory without involving the main processing element 210. While yet in other instances, one or more statistically driven AI models may be used to decide which portion of the processing is performed in-memory and which portion of the processing is performed in main memory by the processing element 210.

Accordingly, the logical operations described herein may be implemented (1) as a sequence of computer implemented acts or one or more program modules running on a computing system and/or (2) as interconnected machine logic circuits or circuit modules within the computing system. The implementation is a matter of choice dependent on the performance and other requirements of the computing system on which the memory system 100 is being used. Accordingly, the logical operations described herein are referred to variously as states, operations, structural devices, acts, or modules. These operations, structural devices, acts, and modules may be implemented in software, in firmware, in special purpose digital logic, and any combination thereof. Greater or fewer operations may be performed than shown in the figures and described herein. These operations may also be performed in a different order than those described herein.

Continuing with the operations described above, and with reference to FIGS. 3C, 3D, and 3E, a store operation (as shown in FIG. 3C) starts by reading the input data (D) and insertion cues (C). Before storing the input data using a new data object, embodiments herein attempt to merge it with an existing data object with similar content. This suboperation (merge attempt) is designed to eliminate storing similar data multiple times. During the merge attempt, a set of candidate data objects (selected based on accessibility with respect to the insertion cues, C) are examined for a good match and the data objects that do not match are penalized by being made less accessible in the NMN. If a data object having a good match with the input data (D) is found, then that matching data object is assigned a higher memory strength and made more accessible in the NMN. After the merge attempt, if a good match is not found, a new data object is instantiated for the input data (D). If a new cue (not present in the cue bank) is found among C, then a new cue object is instantiated for it. Depending on the merge attempt success/failure, the new data object or the matching data object respectively is associated (if already associated, then strengthened) with the insertion cues (C).

The learning aspect of this operation is guided by the input data (D) and cues (C) provided. The candidate data objects for merging are selected using a graph traversal starting from the insertion cues (C). The graph traversal is guided by the NMN structure, hence wrong candidate data object selections are penalized by making those candidate data objects less accessible (by NMN modification). On the other hand, selecting a candidate data object with a good match, with respect to the input data, is rewarded by making that candidate data object more accessible (by NMN modification). Association of the insertion cues (C) with the matching data object or the new data object can also be considered as a learning process.

Continuing with the operations described above, and with reference to FIGS. 3C, 3D, and 3E, a retrieve operation (as shown in FIG. 3C) starts by reading the search cues (C). The search cues consist of a set of coarse-grained cues (C1) and, optionally, a set of fine-grained cues (C2). Based on C1, a set of candidate data objects are selected and are checked for an acceptable match with respect to the fine-grained cues. The candidate data objects that do not match with any fine-grained cue in C2 are made less accessible in the NMN and if a candidate data object matches with any fine-grained cue in C2, then it is made more accessible in the NMN. At the end of the search attempt, if a matching data object is located, then it is provided as output and it also gets associated with all the search cues (C) inside the NMN. In absence of C2, the retrieve operation returns the first accessed candidate data object during the search phase.

Similar to the store operation, the learning in this operation is also driven by the candidate data object selection, which is primarily based on the NMN organization/structure. A wrong candidate selection is penalized and a good candidate selection is rewarded by making necessary NMN state modifications. Association of search cues (C) with the matching data object is also a part of the learning process.

Continuing with the operations described above, and with reference to FIGS. 3C, 3D, and 3E, data retention allows the NMN to change and restructure itself to show the effect of ageing as shown in FIG. 3C. All of the data objects not accessed in the last N-operations (N is a hyperparameter selected by the system admin/user), are weakened. Weakening a data object leads to data feature loss. This sub-operation is a form of reinforcement learning which considers the access pattern and determines which data objects to shrink for saving space. The next sub-operation is also learning-driven, where the accessibility of unused data objects are reduced based on the access pattern.

In comparison to a traditional CAM, embodiments herein are dynamic in several aspects. The NMN of LS changes after every operation and the effect of ageing is captured using the retention procedure. In FIG. 3D, the dynamic nature of LS is illustrated by displaying how the NMN changes during a sequence of operations. Accessibility of different data objects are changed and memory strength of data objects increase or decrease based on the feedback-driven reinforcement learning scheme. In contrast, as seen in FIG. 3E, the traditional CAM does not show any sign of intelligence or dynamism to facilitate data storage/retrieval.

Operations for use with embodiments herein may be further understood with reference to the Appendix of Example Algorithms below.

Write/Store Operation: For storing a data element in example LS frameworks, an example set of processes according to example Algorithm 1 may be considered. M is the LS memory system, D is the data to be stored, S is the search parameters used for data merging attempts, SearchLimit limits the amount of search effort spent on the merge attempt, up can limit the number of changes made to the data object search order, and k allows/disallows association weight decay. At first, the memory hive MH suitable for the data type DT (estimated from D) is selected (line 3). Params is the set of hyperparameters associated with MH (line 4). i (step-size) is the association weight adjustment parameter (line 5). From D, the data features are extracted and stored in DF (line 6). S has three components: C is the set of cues provided by the user that are associated with the given data D, T1 and T2 are used as the association and data feature matching thresholds respectively. In line 10, more cues are extracted (optionally) using AI models from D. The first step of data storage is to ensure that the memory hive MH has enough space to store the incoming data. If the memory lacks space, then, in order to emulate a virtually infinite memory, the framework reduces data features and details of less important data until enough space is created. For example, in a wildlife surveillance system for detecting wolves, a lack of space can lead to compression of image frames without wolves in them. This is an iterative procedure (lines 13-15) and the data-reduction/compression aggressiveness increases with each iteration as shown in example Algorithm 5.

Once enough space is made for the incoming data D, the next step is to determine the locality L, which would be ideal for storing the data D (line 16). L is determined based on the hyperparameter which holds the mapping between data features and localities. Next, a search is carried out to determine if the data D can be merged with an existing data object (lines 21-30). Intelligently merging the incoming data with a pre-existing data object can help save space and increase search efficiency. For example, if the incoming data is almost the same as an already existing data, then there is no need to separately store them. Before the search begins, the search order list is extracted and stored in SO (e.g., using Algorithm 6). The search order list is maintained as a part of the memory M and is a dictionary containing x entries where x is the number of cues currently in the cue bank for the hive MH. Each entry is an ordered list of <Path, DU> pairs arranged in the order of decreasing search priority. The search terminates when either a good match is found or when the SearchLimit is reached. During the search, at each iteration, if the data feature of the candidate/target data object (TargetDN−+DF) has a good match with the data feature of incoming data DF, then the TargetDN is selected for merging. Using the Reaction procedure (Algo. 4), the NMN is updated using reinforcement learning to reflect a success (line 26). Otherwise, the Reaction procedure (e.g., Algorithm 4) updates the NMN using reinforcement learning considering a failed merge attempt (line 28). If the merge candidate search terminates without finding a good match, then a new data object (DN New) is initialized inside the Locality L (line 32) and all the cue objects corresponding to the respective cues in C are associated (if already associated, then strengthened) with it (lines 33-34). If any of these cues are not present in the cue-bank, then new cue objects are generated for those cues. The memory search order is also updated for MH to reflect the presence of the new data object. These <CN, DN> associations thus formed are also a form of learning.

The example reaction (e.g., Algorithm 4) subroutine is a reinforcement learning guided procedure which is used during the store and retrieve operation for creating new associations, changing association weights, and updating search order for cues. MH is the memory hive being updated, TargetDN is the data object which is the focus of the change, Path is the path to the TargetDN, i (step-size) is the association weight adjustment parameter, flag is used to indicate a search/merge success or failure, C is the set of cues used during the search/merge procedure, up is used to allow or disallow memory search order change, and k allows/disallows association weight decay. Each association/connection a in the Path, is either weakened or enhanced depending on the value of flag and k, by an amount i (lines 2-6). If flag==1, then the memory strength of TargetDN is increased (line 8). All the cues Ci in Care associated with TargetDN and if a link exists, then it is strengthened (lines 9-10). Also, if any of these cues are not present in the cue-bank, then new cue objects are generated for the cues. Finally, if up==1, then the memory search order for the memory hive MH is updated to reflect the alternations in NMN.

Read/Load Operation: For the retrieval/load operation, processes according to Algorithm 2 may be considered. In embodiments, this operation may return a data-unit as output. M is the LS memory system, S is the search parameters used for retrieval, SearchLimit limits the amount of search effort spent on the searching attempt, up can limit the number of changes made to the search order, and k allows/disallows association weight decay. At first the memory hive MH is selected based on DT in line 3 (the data type of D). Params is the set of hyperparameters of MH (line 4). From S different components are extracted. C is the set of search cues provided by the memory user, DT is the data type, T 1 and T 2 are used as the association and data feature matching thresholds respectively. Additional cues are extracted optionally using AI models. C1 is the set of coarse-grained cues used for the NMN traversal and C2 is used for determining the data object with a good match. Before the search beings, the search order list is extracted and stored in SO (using Algorithm 6). Next, the search is carried out to determine if a good match can be found (lines 18-28). During the search, at each iteration, if the data feature of TargetDN has a good match with any of the fine-grained cues C2, then the TargetDN is selected for retrieval. In this situation, the Reaction procedure (e.g., Algorithm 4), updates the NMN using reinforcement learning to reflect a success (line 23). Otherwise, the Reaction procedure (e.g., Algorithm 4) updates the NMN using reinforcement learning considering a failure (line 26). Finally, the data selected for retrieval (Ret Data) is returned.

Retention: An example retention procedure in which memories lose features and diminish in prominence over time is presented herein. This procedure can be repeated after a particular interval or can be invoked after certain events. The reinforcement learning guided algorithm to carry out this operation is depicted in Algorithm 3. M is the memory system, Nis the history threshold, and k allows/disallows association weight decay. During this operation, any connections/associations not accessed during the last N-operations are weakened due to inactivity (lines 5-10) and any data objects not accessed in the last N-operations are subject to feature-loss/compression (lines 11-18). The compression rate is limited by the maximum allowed degree of impreciseness (imp degree) for the given memory hive (MH ID). Also, the search order for the cues of each memory hive MH is updated to reflect any changes due to alternation of association weights (lines 19-20).

Elasticity: An example elasticity (e.g., Algorithm 5) subroutine is used during the store operation for making space in-case of a memory shortage. LS framework is designed to operate as a virtually infinite memory where no data is ever deleted but instead unimportant data are subject to feature loss over time. The elasticity hyperparameters are first extracted into elast param from the memory hive MH (line 2). Depending on the current iteration of elasticity (elasticity iter) and the Locality (L), the factor of memory strength decay (line 5), ef is obtained. For each data object D in the locality L, the new memory strength is computed and are compressed if required (lines 6-8). The compression rate is limited by the maximum allowed degree of impreciseness (imp degree) for the given memory hive (MH).

Get Search Order: Algorithm 6 depicts an example subroutine which is used to fetch the search order for a search/merge-attempt. C is the set of cues provided for the operation, MH is the memory hive where the search/merge-attempt is to take place, T1 is the average association weight threshold used to prune candidate data objects and SearchLimit is used to limit the number of candidates selected. For each cue Ci in C, the search order list is fetched from MH and stored in SO (line 5). Then for each candidate in SO, if the average association strength of the candidate is greater than T1, the candidate is appended to the CandidateList. The final CandidateList is returned at the end of the function (line 14) or at line 11, in case of an early exit.

Update Memory Search Order: Algorithm 7 depicts an example subroutine which may be used to update the search order for a given memory hive (MH). Cues holds all the cues in MH. For every cue, C in Cues, the paths to each data object D, with the highest average association strength is selected and stored in decreasing order of average association strength. The NewSearchOrder replaces the previous search order for the MH (line 12).

Update Operation: In traditional CAM, update operation corresponds to changing the data associated with a particular tag/cue or by changing the tag/cue associated with a particular data. Such updates are also possible in LS using retrieve, store and retention procedures. For example, to associate a new tag/cue with a data, one can simply issue a retrieve operation of the target data with the new cue. This will cause the LS system to associate the new cue with the target data. Any old associations of the data with other cues will lose prominence over time if those associations do not get referenced. The storage, retrieval and retention algorithms can be used in many different ways to automatically form new associations and modify existing associations. Traditional CAM also supports data deletion which can be also enabled in LS by setting ‘degree of allowed impreciseness’ hyperparameter to 0. Deletion is not directly achieved in LS but less important data (worthy of deletion) will slowly decay in-terms of memory strength due to lack of access and ultimately disappear.

### Data Storage Module

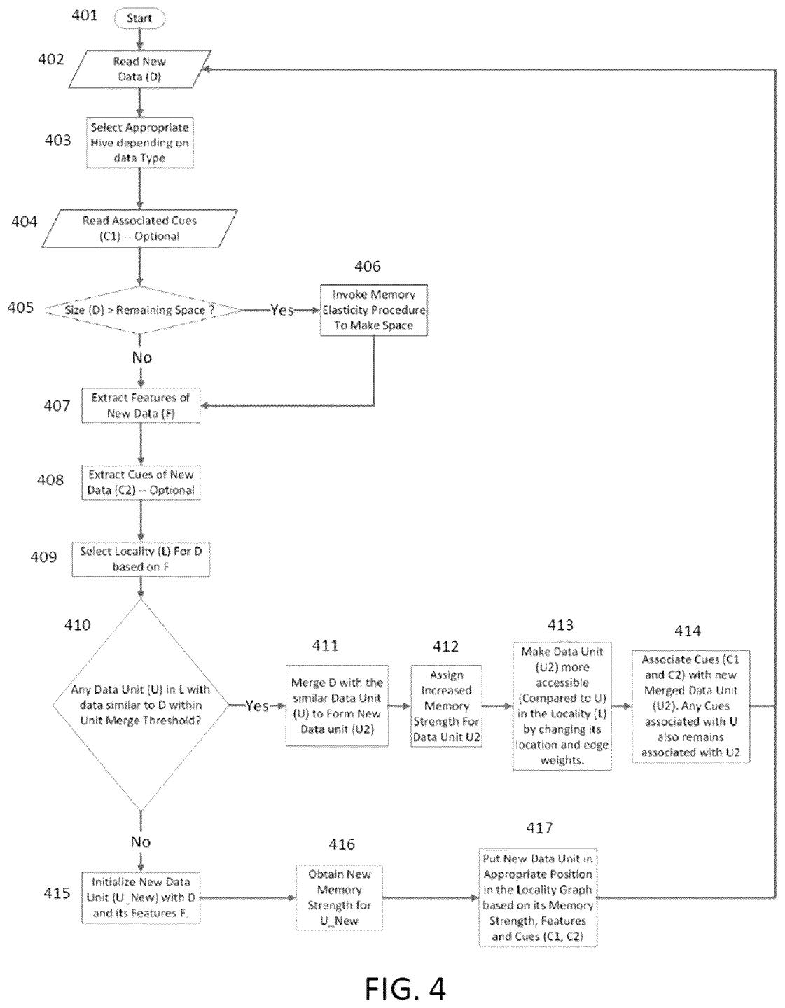

Turning now to FIG. 4, additional details are provided regarding a process flow for storing data in the memory system 100 according to various embodiments. FIG. 4 is a flow diagram showing a data storage module for performing such functionality according to various embodiments of the disclosure. For example, the flow diagram shown in FIG. 4 may correspond to operations carried out by a processing element 210, in-memory, or a combination of both of a computing entity 200 as it executes the data storage module stored in the computing entity's volatile and/or nonvolatile memory.

The memory system 100 begins the data storage module in various embodiments in response to sensing new data in Operation 401. Here, in particular embodiments, the data is to be stored in precise or imprecise form based on the current state of the memory system 100. The data store module responds by reading the new data in Operation 402 and selecting the appropriate memory hive 110, 120 in Operation 403 depending on the data type. In addition, the data storage module may read one or more cues associated with the new data in Operation 404. Here, the cues may be provided to enable more directed faster searching of the new data once stored in the memory system 100.

Next, the data storage module determines whether enough space is available to store the new data in Operation 405. If there is not enough space to store the new data, then the data storage module makes space for the new incoming data frame in Operation 406. Accordingly, in particular embodiments, the data storage module modifies the data units 114a-114e to make more space for the incoming data. This is accomplished in various embodiments without deleting any data in its entirety. However, certain details may get lost. For instance, data units 114a-114e with weak strengths (e.g., data units 114a-114e having older data) may be compressed and similar data units 114a-114e may be merged. In particular instances, the memory elasticity module may carry out this process iteratively with increasing aggressiveness until enough space is made for the new incoming data.

Once there is enough space in memory system 100, the data storage module extracts one or more necessary features from the incoming data using one or more predefined AI models specified during system initialization in Operation 407. In addition, the data storage module may extract one or more cues from the incoming data using one or more predefined AI models in Operation 408. Based on the extracted features and cues, the data storage module determines the locality 111, 113, 121, 123 where the new data is to be stored in Operation 409. Here, in particular embodiments, the data storage module utilizes a data feature-to-locality map in carrying out this operation.

Accordingly, the data storage module compares all the existing data units 114a-114e with the features of the incoming data in Operation 410. In particular embodiments, this comparison may be carried out in an order determined by the cues 116a-116d and an inter-data unit connectivity graph. If the data storage module determines a significant match exists between the features and a particular data unit 114a-114e, then the module merges the incoming data with the similar data unit 114a-114e to form a new merged data unit in Operation 411. Here, the data storage module may determine a significant match exists based on a certain data unit merging threshold specified during initialization.

Upon merging the incoming data with the similar data unit 114a-114e, the data storage module in various embodiments assigns the merged data unit 114a-114e an increased memory strength in Operation 412. In addition, the data storage module adjusts the inter-data unit connectivity graph for the merged data unit 114a-114e to change the data unit's location and edge weight within the locality 111 to make the data unit 114a-114e more accessible in Operation 413. Further, the data storage module associates the cues 116a-116d with the new data unit 114a-114e in Operation 414.

If no data unit merge is possible, then the data storage module instantiates a new data unit 114a-114e for the locality 111 in Operation 415. Accordingly, the data storage module assigns an appropriate memory strength to the new data unit 114a-114e and assigns the new data unit 114a-114e in the appropriate position within the locality 111 based on its memory strength, features, and/or cues in Operations 416 and 417.

### Data Retrieval Module

Turning now to FIG. 5, additional details are provided regarding a process flow for retrieving data from the memory system 100 according to various embodiments. FIG. 5 is a flow diagram showing a data retrieval module for performing such functionality according to various embodiments of the disclosure. For example, the flow diagram shown in FIG. 5 may correspond to operations carried out by a processing element 210, in-memory, or a combination of both of a computing entity 200 as it executes the data retrieval module stored in the computing entity's volatile and/or nonvolatile memory.

The memory system 100 begins the data retrieval module in various embodiments in response to a query to fetch stored data in Operation 501. Accordingly, the data retrieval module reads the retrieval mode in Operation 502. For instance, in particular embodiments, the retrieval modes Top-N and First-N may be used. Here, for a Top-N retrieval, the best N matches are retrieved. While for a First-N retrieval, the first N matches within a certain threshold are retrieved.

In addition, depending on the embodiment, the data retrieval module reads the query data type, the query raw data/features, matching threshold, number of maximum matches, and/or cues in Operations 503, 504, 505, 506, and 507. Here, these are read by the data retrieval module as input based on, for example, input entered by a user and/or provided by a software application.

Accordingly, the data retrieval module may extract one or more additional cues from the data based on the raw data/features in Operation 508. Here, in particular embodiments, the data retrieval module may make use of one or more AI models that were specified during initialization to extract the one or more cues. In addition, the data retrieval module may extract one or more features based on the raw data in Operation 509. Here, in particular embodiments, this operation may only be carried out if the input read by the data retrieval module does not include any features. Again, in particular embodiments, the retrieval module may make use of one or more AI models that were specified during initialization to extract the one or more features.

Next, the data retrieval module selects a hive 110, 120 based on the data type for the query and a search entry point for the hive 110, 120 based on the cues 116a-116d in Operation 510. As previously noted, in various embodiments, each hive 110, 120 found within the memory system 100 is associated with a specific data type. Once the hive 110, 120 has been identified, the data retrieval module traverses the intelligent weighted graph for the hive 110, 120 based on the data features and cues 116a-116d in Operation 511. Accordingly, a determination is made by the data retrieval module for each data unit 114a-114e encountered during the traversal whether the data unit 114a-114e is to be fetched or not.

If retrieval mode is First-N in Operation 512, then the data retrieval data module retrieves the data units 114a-114e with data features similar to the query features within the matching threshold in Operation 513. As a result, the data retrieval module increases the strength of these retrieved data units 114a-114e, adjusts the inter-data unit connectivity graph of their localities 111, 113, 121, 123 accordingly, and forms new cue-to-data unit associations 117a-117b as needed, as well as adjust the weights for some existing cue-to-data unit associations 117a-117b in Operation 514. The data retrieval module then provides the First-N data units within the matching threshold as output in Operation 515.

If retrieval mode is Top-N instead, then the data retrieval module retrieves the data units 114a-114e with the best degree of match with the query features in Operation 516. Accordingly, the data retrieval module increases the strength of the retrieved data units 114a-114e, adjusts the inter-data unit connectivity graph of their localities 111, 113, 121, 123 accordingly, and forms new cue-to-data unit associations 117a-117b as needed, as well as adjust the weights for some existing cue-to-data unit associations 117a-117b in Operation 517. The data retrieval module then provides the First-N data units within the matching threshold as output in Operation 518. Accordingly, the process flow ends in Operation 519.

### Data Retention Module

The memory system 100 in various embodiments is allowed to merge memories, reorganize memories, compress memories, relocate memories, and otherwise execute similar routine tasks in the background. These tasks are carried out after a particular interval or after certain events.

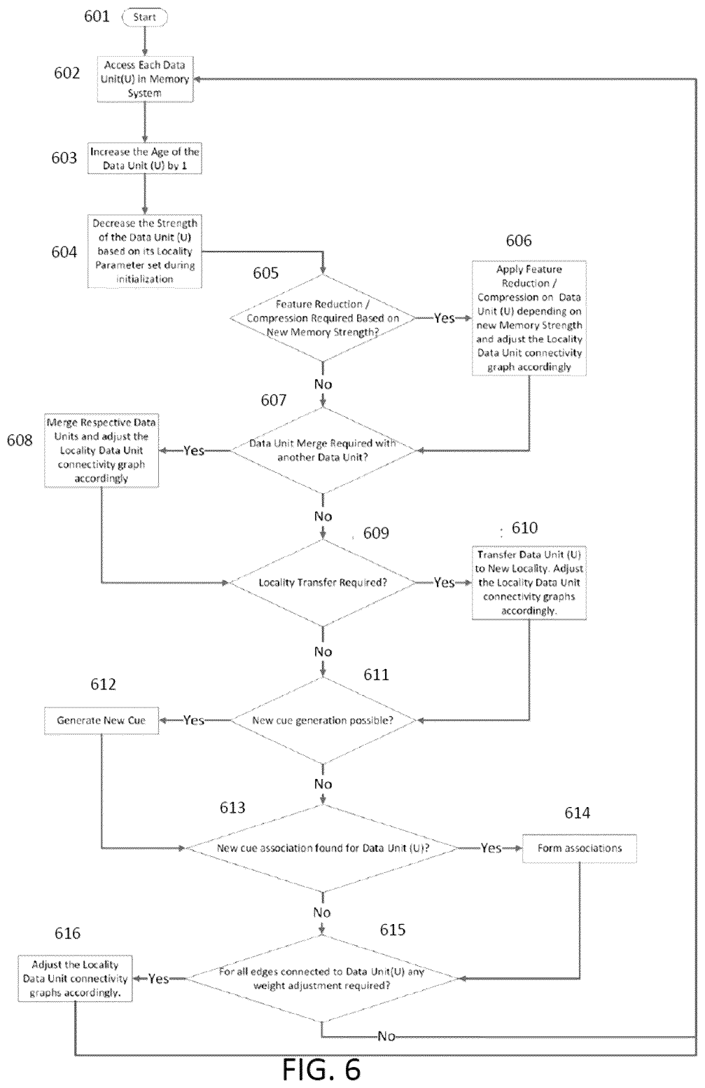

Thus, turning now to FIG. 6, additional details are provided regarding a process flow for retraining data with the memory system 100 according to various embodiments. FIG. 6 is a flow diagram showing a data retention module for performing such functionality according to various embodiments of the disclosure. For example, the flow diagram shown in FIG. 6 may correspond to operations carried out by a processing element 210, in-memory, or a combination of both of a computing entity 200 as it executes the data retention module stored in the computing entity's volatile and/or nonvolatile memory.

The memory system 100 begins the data retention module in various embodiments in Operation 601. Accordingly, the data retention module accesses each data unit 114a-114e in the memory system in Operation 602. Here, the data retention module increases the age of each data unit 114a-114e by some amount (e.g., one) in Operation 603 and decreases the strength for each data unit 114a-114e based on one or more memory system parameters in Operation 604.

At this point, the data retention module determines whether a feature reduction and/or compression is required based on the newly set age and strength, as well as the memory activity history, for each data unit 114a-114e in Operation 605. If feature reduction and/or compression is required for a particular data unit 114a-114e, then the data retention module applies feature reduction and/or compression on the data unit 114a-114e based on the memory strength and adjusts the locality's inter-data unit connectivity graph accordingly in Operation 606.

The data retention module next determines whether a data unit merge is required between the particular data unit 114a-114e and another data unit 114a-114e in Operation 607. If so, then the data retention module merges the respective units 114a-114e and adjusts the locality's inter-data unit connectivity graph accordingly in Operation 608. The data retention module then determines whether the particular data unit 114a-114e needs to be transferred to another locality 111, 113, 121, 123 in Operation 609. If so, then the data retention module transfers the data unit 114a-114e to the new locality 111, 113, 121, 123 and adjusts the corresponding localities' inter-data unit connectivity graphs accordingly in Operation 610.

In addition, the data retention module determines whether any new cues 116a-116d need to be generated for the particular data unit 114a-114e in Operation 611. If so, then the data retention module generates the new cues 116a-116d for the data unit 114a-114e in Operation 612. Further, the data retention module determines whether any new cue-to-data unit associations 117a-117b can be found for the particular data unit 114a-114e in Operation 613. If so, then the data retention module forms the new cue-to-data unit associations 117a-117b for the data unit 114a-114e in Operation 614. Finally, the data retention module determines whether the weight for any of the edges connected to the particular data unit 114a-114e need to be adjusted in Operation 615. If so, then the data retention module adjusts the inter-data unit connectivity graphs accordingly in Operation 616. As noted, in various embodiments, the data retention module repeats these operations for each of the data units 114a-114e found in the memory system 100.

### Data Update Modules

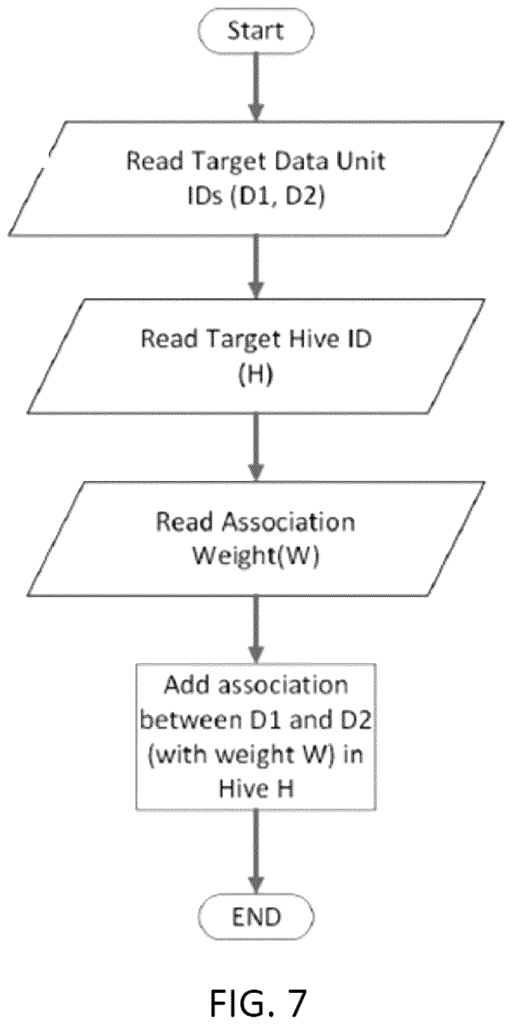

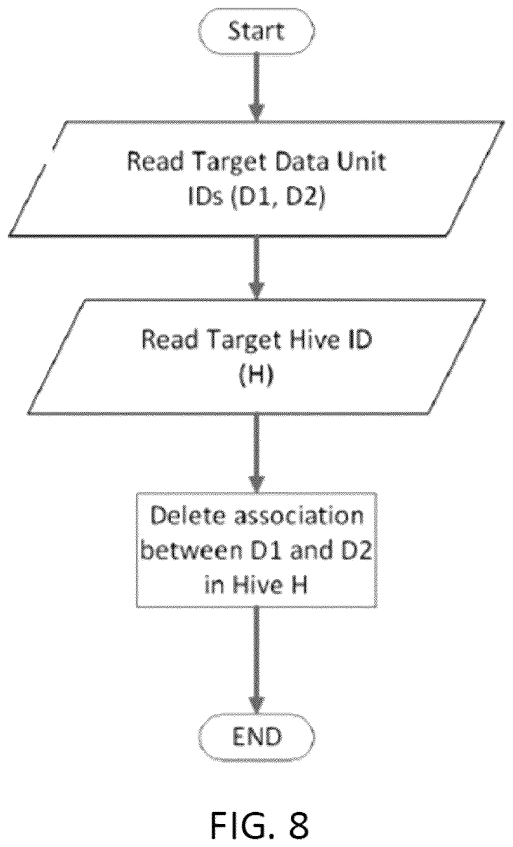

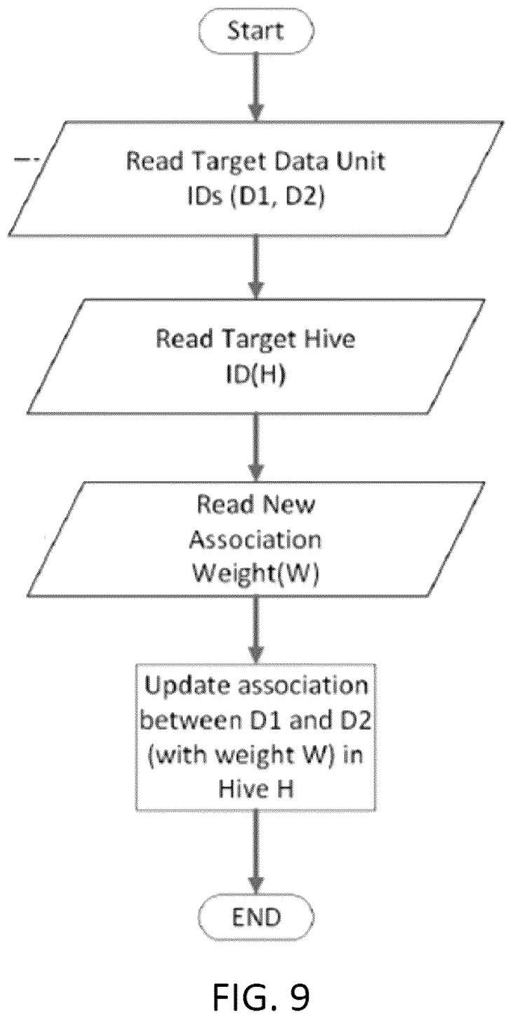

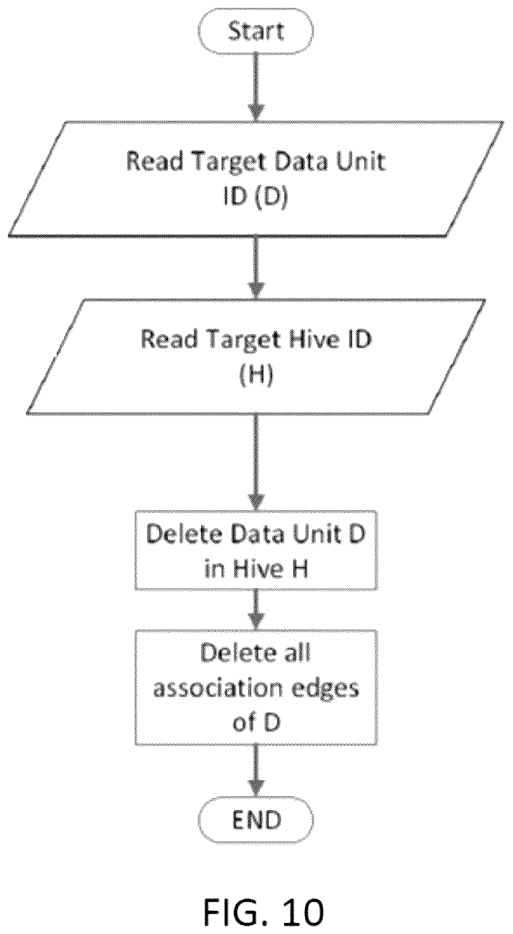

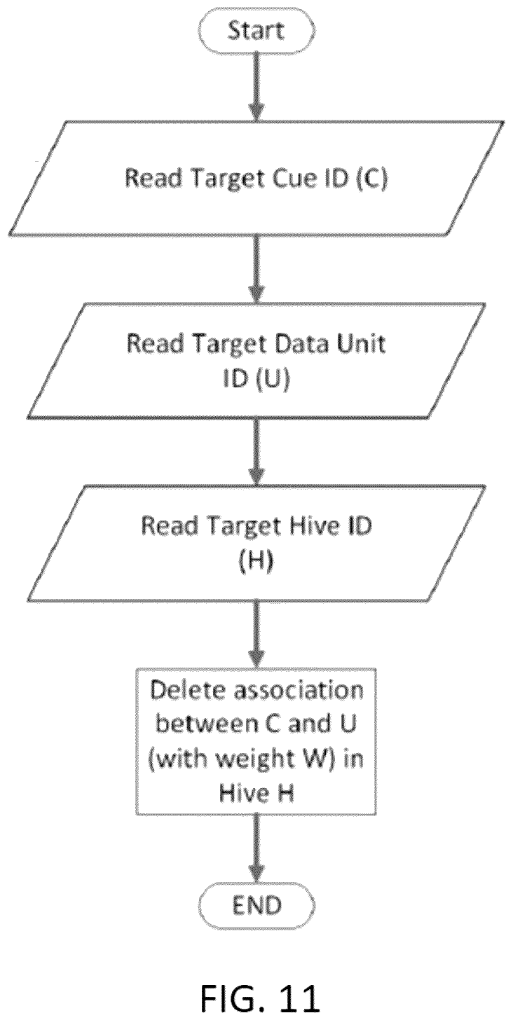

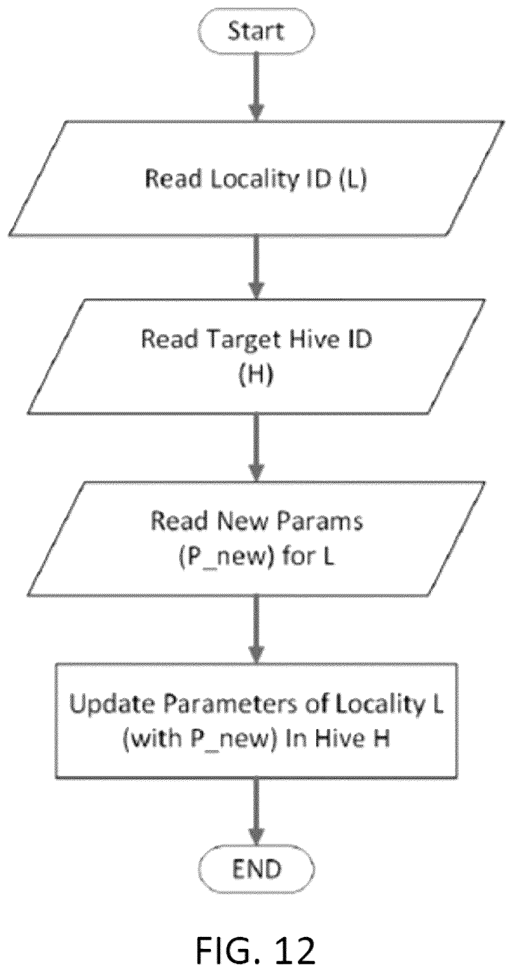

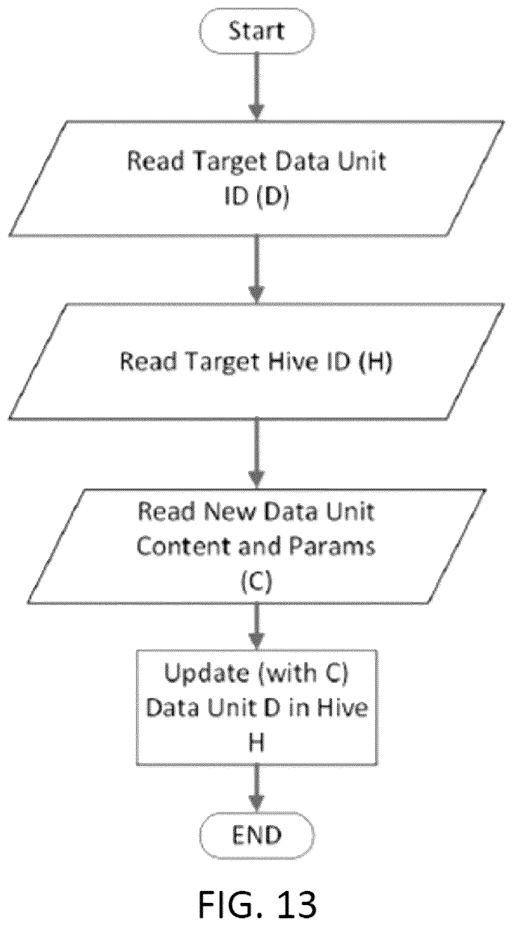

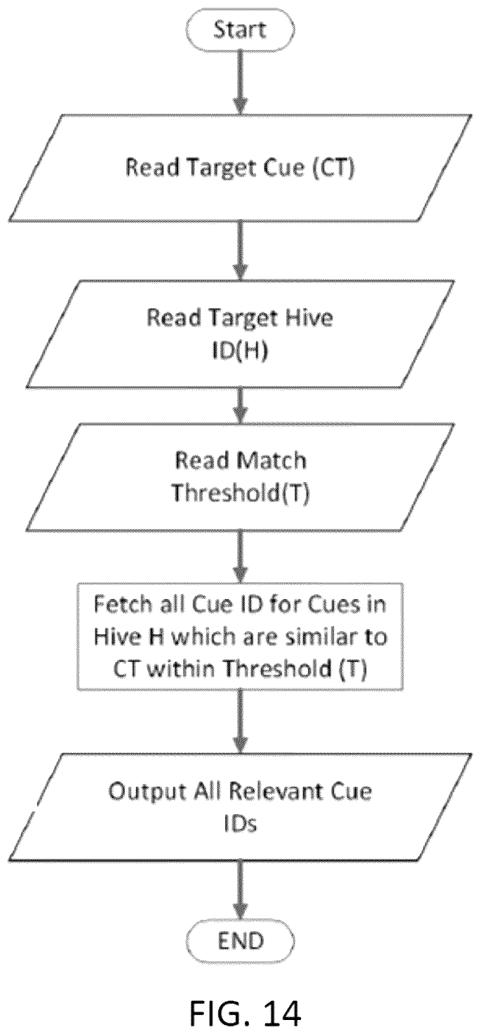

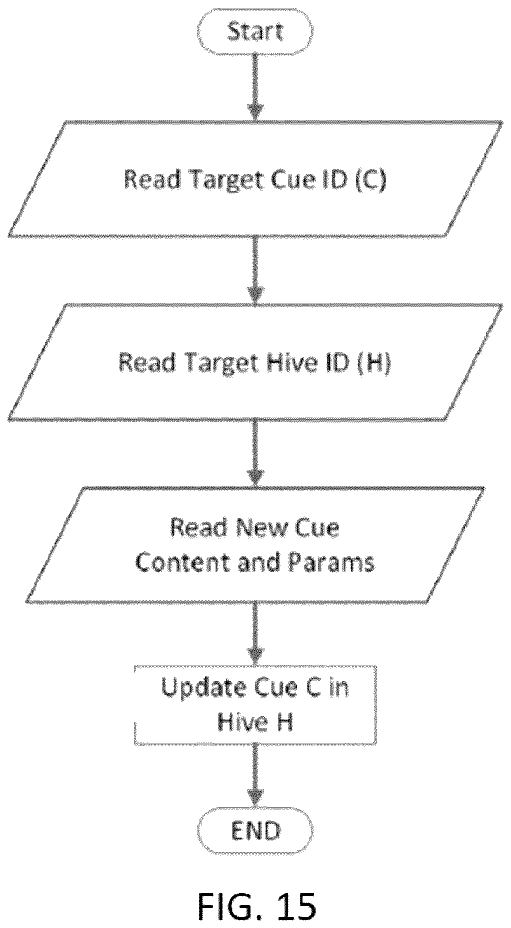

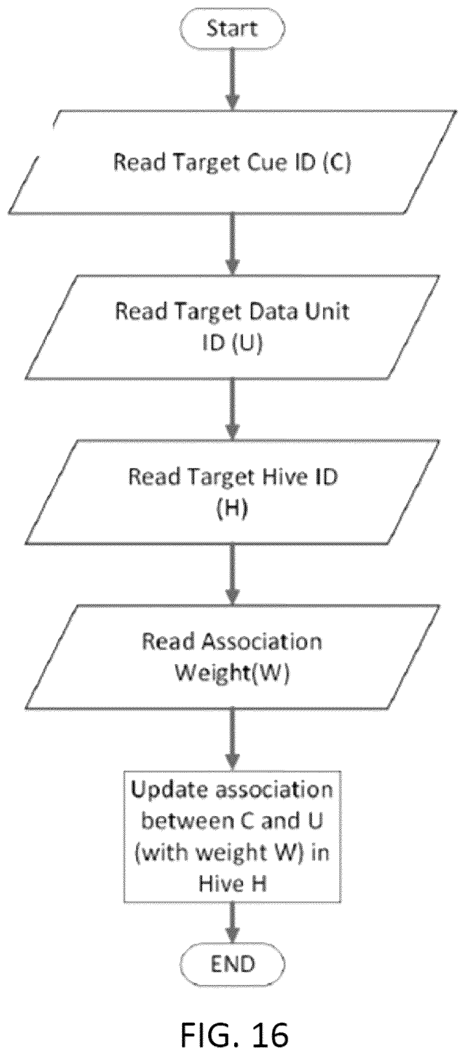

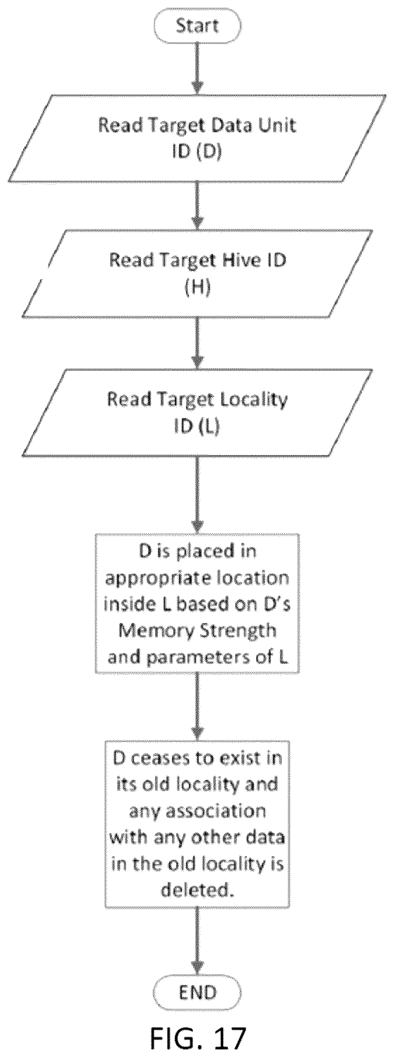

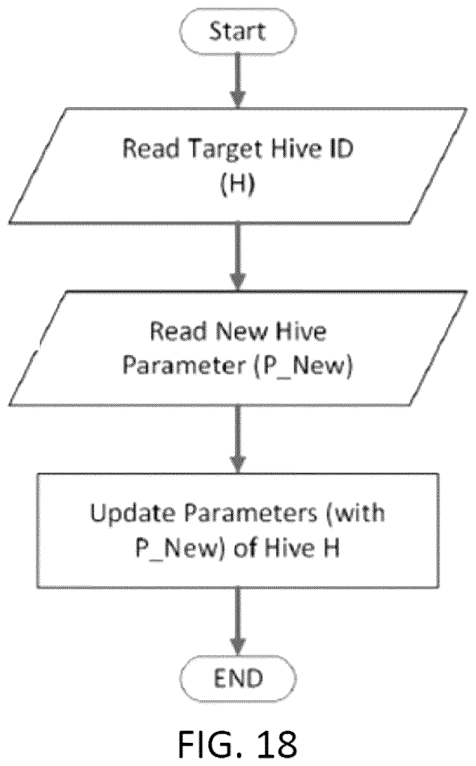

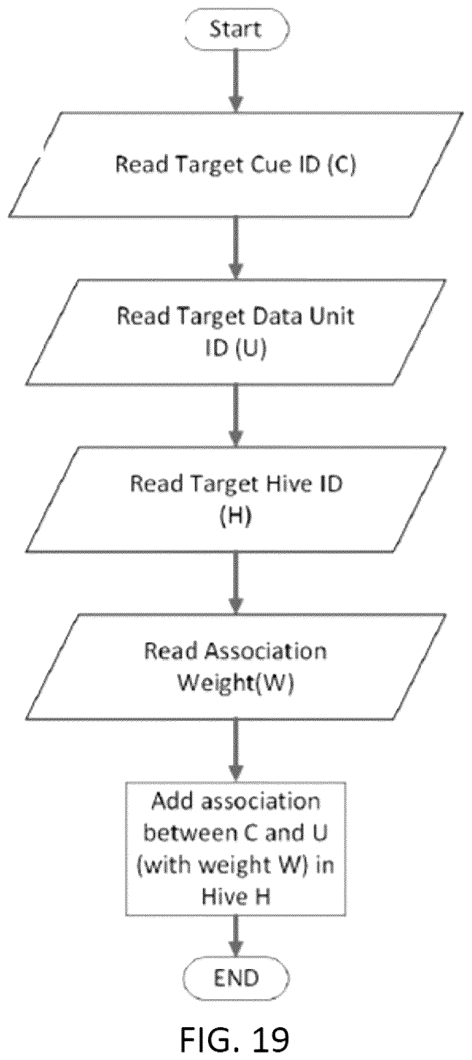

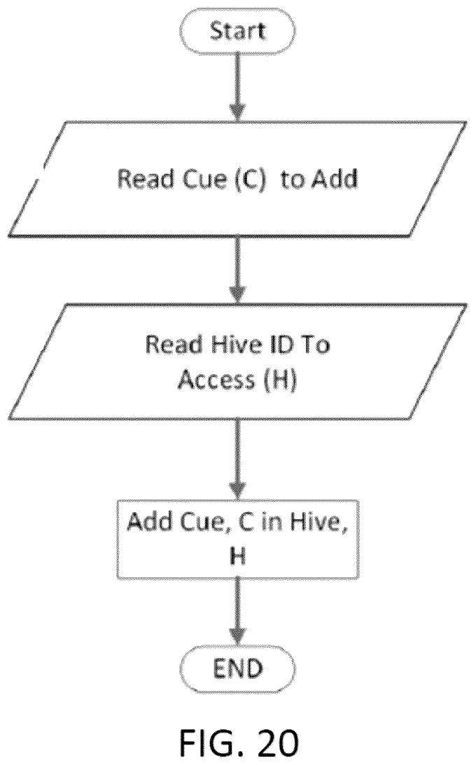

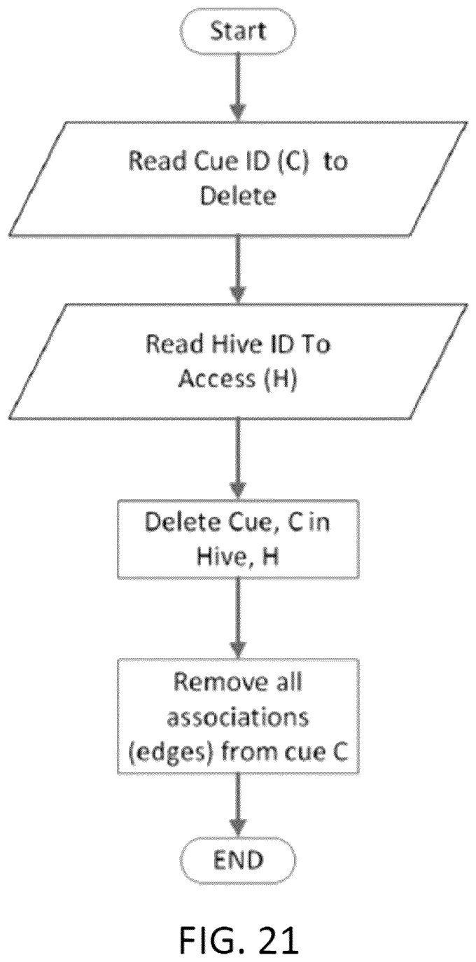

Various embodiments of the disclosure may also include one or more modules for performing various administrative operations that may be used in modifying certain content in the memory system 100. The process flows for these various operations are shown in FIGS. 7-21 according to various embodiments of the disclosure. Specifically, FIG. 7 details a process flow for adding a new association between two data units 114a-114e. FIG. 8 details a process flow for deleting an association 115a-115b between two data units 114a-114e. FIG. 9 details a process flow for updating an association 115a-115b between two data units 114a-114e. FIG. 10 details a process flow for deleting a data unit 114a-114e. FIG. 11 details a process flow for deleting an association 117a-117b between a cue 116a-116d and a data unit 114a-114e. FIG. 12 details a process flow for changing the parameters of a locality 111, 113, 121, 123. FIG. 13 details a process flow for updating the parameters and content of a data unit 114a-114e. FIG. 14 details a process flow for fetching the cue identifiers of all cues 116a-116d in the memory system 100 similar to a query cue. FIG. 15 details a process flow for modifying the content of a cue 116a-116d. FIG. 16 details a process flow for updating an association 117a-117b between a cue 116a-116d and a data unit 114a-114e. FIG. 17 details a process flow for transferring a data unit 114a-114e from one locality 111, 113, 121, 123 to another. FIG. 18 details a process flow for changing the parameters of a hive 110, 120. FIG. 19 details a process flow for adding a new association 117a-117b between a data unit 114a-114e and a cue 116a-116d. FIG. 20 details a process flow for adding a new cue 116a-116d to a hive 110, 120. Finally, FIG. 21 details a process flow for deleting a cue 116a-116d in a hive 110, 120.

### SIMI: Selective In-Memory Inferencing

Various embodiments of the disclosure allow certain memory modification actions to be performed in-memory while the rest of the actions are performed in the main processing unit after fetching the relevant data. In particular embodiments, the decision of which portion of the action is to be done in-memory and which portion of the action is to be done in main memory is determined using one or more statistically driven online AI models. This particular feature may be referred to as Selective In-Memory Inferencing (SIMI) and may be used in conjunction with the process flows shown in FIGS. 4-21.

### Co-Existence of Precise and Imprecise Memory Retention: Locality Selection

Various embodiments of the disclosure employ concepts that can allow more precise storage of certain types of data (e.g., as specified by a user) and sacrifice details for other data. For instance, in particular embodiments, precise data and different levels of imprecise data can be placed in different localities 111, 113, 121, 123 of a memory hive 110, 120. In some embodiments, the locality 111, 113, 121, 123 containing precise data may be set to not use feature reduction allowing the data to be one-hundred percent precise.

### Cue-Guided Feature-Based Information Storage and Retrieval

With respect to various embodiments of the disclosure leverage feature-driven storage and retrieval techniques wherein each data unit 114a-114e can hold the features extracted from its data. Additionally, cues 116a-116d can be associated with different data units 114a-114e to allow faster search. These data features and associated cues 116a-116d can be used during memory retrieval, memory storage, memory retention, and memory processing as demonstrated in the process flows shown in FIG. 4-21.

In-Memory Associations and Cue Based retrieval

Various embodiments of the disclosure provide faster search speeds by associating memories with one another by adding a cue bank 112, 122 in memory hives 110, 120 and connecting data units 114a-114e inside localities 111, 113, 121, 123 using weighted bi-directional edges. Cues 116a-116d can be associated with data units 114a-114e as-well. The cue-to-data unit associations 117a-117b and data unit-to-data unit associations 115a-115b can change over time in particular embodiments as more operations are performed and more stimulus encountered.

### Memory Strength Decay

Various embodiments of the disclosure enable accessibility regression and gradual feature granularity loss by allowing data units 114a-114e to lose strength and features over time. In particular embodiments, the inter-data unit connectivity graphs may also be modified to make data less and less accessible as compared to other data units 114a-114e of higher strength. Lost memory strength can however recover in some embodiments if the data units 114e-114e become re-enforced.

### Memory Re-Enforcing by Recalling and Data Unit Merging

a memory can be re-enforced: (1) if similar/same memory is encountered as an external stimuli and (2) if the memory is recalled. Various embodiments of the disclosure enable data units 114a-114e in the memory system 100 to be re-enforced: (1) when a memory meeting a threshold similarity is encountered, and (2) if the corresponding memory is successfully recalled. For instance, when storing new data, various embodiments try to find data units 114a-114e that may contain very similar data and attempt a data unit merger, resulting in a merged data unit 114a-114e having increased memory strength and better accessibility. Also when a data unit 114a-114e is retrieved in some embodiments, that particular data unit 114a-114e is re-enforced, resulting in increased memory strength and better accessibility.

### Memory Spatial Distribution: Via Memory Vein Selection

Various embodiments of the disclosure enable improved speed when fetching a memory collection related to a particular concept by dividing a memory hive 110, 120 into multiple memory localities 111, 113, 121, 123 to store data containing different concepts. For instance, in some embodiments, the locality selection process is carried out by the data storage module described above that determines which locality 111, 113, 121, 123 should hold the new incoming data. In particular embodiments, this selection is performed by the module using one or more AI models for feature extraction and system initialization parameters such as the mapping between data features and localities.

### Memory Elasticity: Practically Infinite Memory

Various embodiments of the disclosure store large amounts of data by retaining a set of most important memories and storing additional memories with decreased feature granularity. Although data units 114a-114e are not completely deleted (unless express instruction is provided to do so), they can lose features as a result of their memory strength dropping. If the system 100 starts to run out of space, more aggressive compression and data unit merging measures are used in various embodiments to make space.

### Memory Plasticity: Dynamic Memory Retrieval Priority Changing and Variable Speed Content Recovery

Various embodiments of the disclosure allow the inter-data unit connectivity graphs to change during data retrieval, data storage, retention and update tasks as demonstrated in the process flows shown in FIGS. 4-21. This reorganization and formation of new connections between data items enables faster search speed when accessing important current scenario relevant memories.

### Massively Parallel Content Based Memory Access

Various embodiments of the disclosure provide a variable degree of parallelization wherein memory contents are accessed in parallel to fetch the most relevant contents, thereby enabling large memory spaces to be searched quickly. In particular embodiments, the amount of parallelization used is determined by a user and/or system design.

### Intelligent Learning Memory

In various embodiments, the memory system 100 may be constantly evolving. In particular embodiments, the system 100 optimizes memory depending on the demand, external stimulus, and current memory state. In some embodiments, the optimization may be based on a learning-based algorithm that can evolve side-by-side with the memory system 100. A few key aspects can contribute towards the intelligence of the memory system 100 such as:

Importance of Data: The importance of data in the system 100 can constantly evolve. For instance, depending on access, new data input, and background processing, the importance of data can change. Accordingly, the memory strength of data can grow and shrink, data unit-to-data unit associations 115a-115b can change, and multiple data units 114a-114e can be merged to save space and re-enforce old data. In particular embodiments, these operations can be learning driven based on statistical information.

Formation of Cues and their Associations with Data Units: Cues 116a-116d can be used to bolster the search speed of data in various embodiments. New cues 116a-116d can be constantly learned in the memory system 100 and associations 117a-117b between cues 116a-116d and data units 114a-114e can change over time. In particular embodiments, these changes are made automatically during data access, storage, and updates. In addition, in particular embodiments, these operations can be learning driven based on statistical information.

Amount of Information in Data Units: In various embodiments, data units 114a-114e can loss information for data during the lifecycle of the system 100 due to lack of re-enforcing and access. In particular embodiments, how much information to retain and what information to retain can be determined using one or more AI models based on statistical information. In addition, certain data units 114a-114e may be identified as more precious than others based on intelligence obtained over time.

### System Formalism, API and Interface of Various Embodiments

As previously noted, various embodiments of the memory system 100 can be used to replace conventional memory components of many application systems without requiring much effort. In addition, many of the operations shown herein can be performed to achieve the basic functionalities of a memory system. Further, new functionality can be added to various embodiments with little effort. In various embodiments, the initialization parameters previously described are set during the system initialization and once set, no other administrative operation is required. In addition, certain performance parameters such as average data retrieval time, average retrieval quality, average space requirement, etc. can be used to measure the effectiveness of certain settings of these initialization parameters. Further, during initialization, a small dataset can be used to calibrate the system. Finally, in particular embodiments, the initialization parameters can be also be modified during system operation based on statistical data to ensure optimized memory utilization.

### Simulation Results and Analysis

In order to quantitatively analyze the effectiveness of LS in a computer system, embodiments herein include design and implementation of an LS simulator. It has the following features:
It can simulate all memory operations and provide relative benefits with respect to traditional CAM in terms of operation cost;
The framework is configurable an array of hyperparameters introduced herein;
The LS simulator can be mapped to any application which is designed for using a CAM or a similar framework;
The LS simulator is scalable and can simulate a memory of arbitrarily large size; and
To ensure correctness, the simulator software is validated through manual verification of multiple random case studies with a large number of random operations.

Operation cost is defined herein as the amount of effort it takes to perform a particular operation. It is clear that the iterative search-section of the LS operations (e.g., FIGS. 3B-3E), dominates over the remaining sub-operational steps in terms of effort. Hence, the operation cost for LS is considered herein to be the number of times the search-section is executed for both store and retrieve operations. For the traditional CAM, the operation cost is considered herein to be the number of data entries searched/looked-up. For both traditional CAM and LS, parallelism while searching is ignored to ensure fairness. Also, the cost of writing the data to the memory for both LS and traditional CAM is not considered as a part of the operation cost. For LS, the effort of writing the data to the memory is less than or equal (in the worst case, due to data merging) to that of the traditional CAM.

### Desirable Application Characteristics

Any application using a CAM or a similar framework can be theoretically replaced with LS. However, certain applications will benefit more than others. Two example characteristics of an application which will enhance the effectiveness of LS are described below.

Imprecise Store & Retrieval: Although LS can be configured to operate at 100% data precision, it is recommended to use the framework in the imprecise mode for storage and search efficiency. Assume D=Set of data objects in the Memory at a given instance. For a given data Dᵢ ∈M, if Dᵢ is compressed (in lossy manner) to Dᵢ′ and (size(Dᵢ)=size(Dᵢ′)−∈₁), then in order for the application to operate in the imprecise domain, it must be that (Quality(Dᵢ′)=Quality(Dᵢ′)−∈₂). Where size(X) is the size of the data object X and Quality(X) is the quality of the data in the data object X, in light of the specific application. ∈₁ and ∈₂ are small quantities. For example, in a wildlife surveillance system, if an image containing a wolf is compressed slightly, it will still look like an image with the same wolf.

Notion of Object(s)-of-Interest: LS works best if there exists a set of localities within each hive which are designated to store data containing specific objects. Each locality can be configured to have different memory strength decay rate based on the importance of the data which are designated to be stored in the respective locality. Note that the definition of an object in this context implies specific features of the data. For example, in case of an image data, the object can be literal objects in the image but for a sound data, the objects can be thought of as a specific sound segment with certain attributes. Assume that D is a new incoming data which must be stored in the Memory and OL=objects in data D. Then there may be situations where, ∃O₁, O2 ∈OL|Imp(O_1)>Imp(O_2). Where Imp(O_i) denotes the importance of the object O_i for the specific application. For example, in wildlife surveillance designed to detect wolves, frames containing at least one wolf should be considered with higher importance.

To evaluate the effectiveness of LS, two image datasets were selected from two representative applications: (1) wildlife surveillance system and (2) a UAV-based security system. For both applications, traditional CAM can be used for efficient data storage and retrieval. A comparative study between LS and traditional CAM for these datasets in terms of several key memory access parameters was conducted and is presented herein. To model LS behavior for the target dataset, the simulator as described below was used, while traditional CAM behavior is modelled based on standard CAM organization.

### Simulator Configuration

Connections between cue objects are not formed. Search order entries have a path length of 1. Every locality has a “default cue” which is connected with all the data objects in the locality and is used to access data objects which are not otherwise accessible from normal cues. This construct emulates <DN, DN> associations. For all the case studies, a single memory hive was used for holding the image data. For this specific hive the following hyperparameters were used:
Number of localities (Lₙ): 2.
Memory decay rate of each locality: [0.5, 1]
Association decay rate of each locality: [0, 0]
Mapping between data features and localities: Depends on the application and case-study.

Wildlife Surveillance: For scenario 1, deer images are mapped to locality 0 and other images are mapped to locality 1. For scenario 2, wolf/fox images are mapped to locality 0 and other images are mapped to locality 1.

UAV-based Security System: Car images are mapped to locality 0 and other images are mapped to locality 1.

Data features and cue extraction AI (Artificial Intelligence) models: VGG 16 predicted classes are used as coarse-grained cues. For data feature and fine-grained cues, VGG 16 fc2 activations are used. Data Object matching metric: Cosine-Similarity.

Elasticity parameters:
0→[80, 70, 60, 50, 40, 30 20, 10]
1→[80, 70, 60, 50, 40, 30 20, 10]

Association weight adjustment parameter: 20. Degree of allowed impreciseness: 1. Frequency of retention procedure: 500. Compression technique: JPEG compression was used for the image hive.

Operation parameters were used during all store, retrieve and retention operations/procedures unless otherwise specified.
S→Assoc_Thresh: 0
S→Match_Thresh: 0.95
SearchLimit: Maximum (Int_Max)
up=1
k=0.

A quantitative analysis on the benefits of using LS over traditional CAM is presented below.

### Wildlife Surveillance

Image sensors are widely deployed in the wilderness for rare species tracking and poacher detection. The wilderness can be vast and IoT devices operating in these regions often deal with low storage space, limited transmission bandwidth and power/energy shortage. This demands efficient data storage, transmission and power management. Interestingly, this specific application is resistant to imprecise data storage and retrieval because compression does not easily destroy high-level data features in images. Also, in the context of this application, certain objects such as a rare animal of a specific species are considered more important than an image with only trees or an unimportant animal. Hence this application has the desirable characteristics suitable for using LS and will certainly benefit from LS's learning guided preciseness modulation and plasticity schemes. Informed reduction of unnecessary data features will also lead to less transmission bandwidth requirements. Memory power utilization is proportional to the time required to carry out a store, load and other background tasks. And LS, due to its efficient learning-driven dynamic memory organization, can help reduce memory operation time and consequently can reduce overall operation effort. Furthermore, transmitting the optimal amount of data (instead of the full data) will lead to lesser energy consumption as transmission power requirement is often much higher than computation.

Dataset Description: To emulate a wildlife surveillance application, an image dataset is constructed from a wildlife camera footage containing 40 different animal sightings. Two different scenarios are constructed for carrying out experiments on this dataset:
Scenario 1: The system user wishes to prioritize deer images and perform frequent deer image retrieval tasks.
Scenario 2: The system user wishes to prioritize fox/wolf images and perform frequent fox/wolf image retrieval tasks.

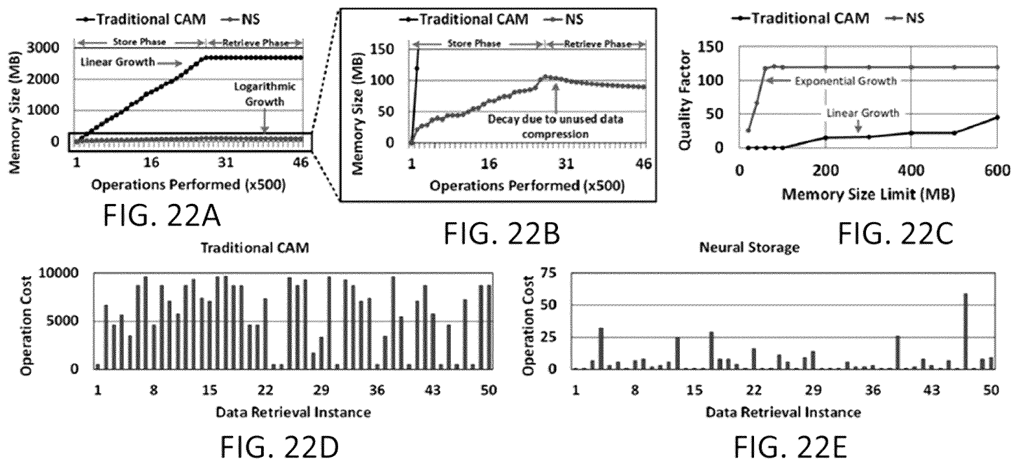

Effectiveness of LS in Comparison to Traditional CAM: Both the LS framework and the traditional CAM are first presented with all the images in the dataset sequentially and then a randomly pre-generated access pattern (based on the scenario) is used to fetch 10,000 images (non-unique) sampled from the dataset. For scenario-1, as can be seen in FIG. 22A, LS has a clear advantage over traditional CAM in terms of total space utilization. It is also observed in the zoomed-in graph, FIG. 22B, the LS total space utilization fluctuates and slowly decreases after the end of the store phase. This is due to access pattern guided optimal data granularity learning resulting in compression/feature-loss of less important data. In FIG. 22D and FIG. 22E, the operation cost is illustrated during the first 50 retrieve operations for traditional CAM and LS respectively. The operation cost for the LS in comparison to traditional CAM is significantly lower.

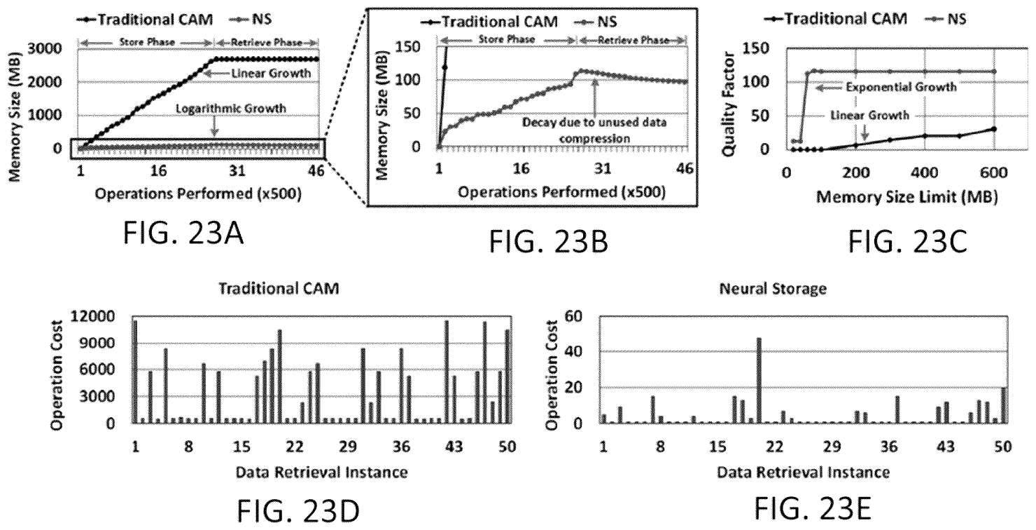

In Table 2, the numerical details of the experiments are summarized. The average operation cost (store and retrieve combined) for LS is about 165 times less than that of traditional CAM. It is worth noting that the PSNR (Peak signal-to-noise ratio) and SSIM (Structural similarity) of the fetched images during retrieve operations for LS have similar values as that of traditional CAM. This ensures that using the LS framework for this application will not affect the effectiveness of the application. The same experiments were then repeated with locality-0 tuned to store only fox/wolf frames (scenario-2). In FIGS. 23A-23E and Table 2, similar trends are observed.

Effectiveness of LS in Constrained Settings: Most of the image sensors used in a wildlife surveillance system are deployed in remote locations and must make efficient use of bandwidth and storage space without sacrificing system performance. LS is designed to excel in this scenario and to verify this, the total memory size (X-axis) is limited and the memory quality factor (Y-axis) is plotted in FIG. 22C (scenario-1) and FIG. 23C (scenario-2). The memory quality factor is defined in Eqn. 1. In both the scenarios, LS appears capable of functioning at a much lower memory capacity in comparison to Traditional CAM. Lower space utilization also translates to less transmission bandwidth consumption, in-case the system has to upload the stored data to the cloud or other IoT devices. Also, it is noted that the quality factor of the LS framework increases exponentially with the increase in memory size limit whereas the quality factor of the traditional CAM increases at a much slower pace.

$$Quality Factor = PSNR + ( 100 ⋆ SSIM ) \qquad ( 1 )$$

### UAV-Based Security System

UAV-based public safety monitoring is a critical application which is often deployed in remote areas with limited bandwidth and charging facilities. Additionally, UAVs by design must deal with small battery life and limited storage space. Hence, this application operates in a space, power and bandwidth constraint environment. However, this application is resistant to imprecise storage and retrieval because it deals with images which retain most of the important features even after compression/approximation. And, a UAV roaming over different regions captures plenty of unnecessary images which may not be important for the application's goal/purpose. Hence there is a notion of object(s)-of-interest. All of these characteristics and requirements, make this application ideal for using LS.

Dataset Description: To capture the application scenario, a dataset containing UAV footage of a parking-lot was created. The UAV remains in motion and captures images of cars and people in the parking lot. The experiments were created with the assumption that the system user wishes to prioritize car images and perform frequent car image retrieval tasks.

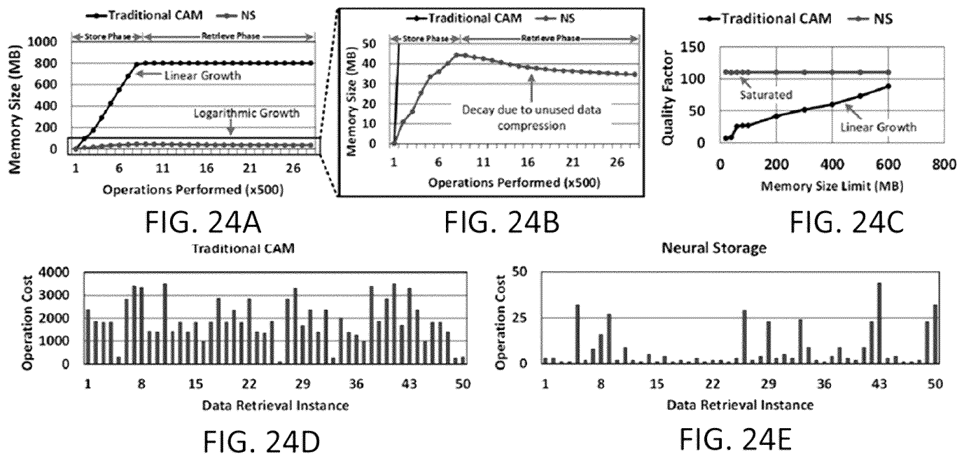

Effectiveness of LS in Comparison to Traditional CAM: A similar trend is noted as observed for the wildlife surveillance system. The memory space utilization graph in FIG. 24A, shows that the LS framework is much more space-efficient than traditional CAM. In the zoomed-in portion, FIG. 24B, it is observed that the memory space utilization decays after the store phase, due to compression of data which are not being accessed. In FIGS. 24A-24E, LS is observed to be more efficient in terms of retrieval operation cost due to its learning guided dynamic memory organization (operation cost is estimated as described herein). From Table 2, it is observed that LS is about 65× more efficient in terms of average operation cost (store and retrieve combined). Furthermore, in Table 2, it is noted that the PSNR and SSIM of the fetched images during retrieve operations are similar for LS and traditional CAM. Thus it evident that the LS framework is equally effective as a traditional CAM in terms of serving the application.

TABLE 2
Simulation Results

| | | | | | | |
|---|---|---|---|---|---|---|
| | | | Avg. Retrieval | Avg. Store | Avg. Op. | Final Memory |
| Mem. Type | PSNR | SSIM | Op. Cost | Op. Cost | cost | Size (MB) |

Wildlife Surveillance: Emphasis on Deer (Scenario-1)

| | | | | | | |
|---|---|---|---|---|---|---|
| Trad. Cam | 37.65 | 0.79 | 5573.93 | 0 | 2786.96 | 2688.79 |
| LS | 38.39 | 0.82 | 5.51 | 28.23 | 16.87 | 89.46 |

Wildlife Surveillance: Emphasis on Fox (Scenario-2)

| | | | | | | |
|---|---|---|---|---|---|---|
| Trad. Cam | 37.11 | 0.75 | 3306.83 | 0 | 1653.41 | 2688.79 |
| LS | 38.52 | 0.79 | 4.39 | 22.96 | 13.67 | 97.40 |

UAV-based Surveillance for Safety: Emphasis on Car

| | | | | | | |
|---|---|---|---|---|---|---|
| Trad. Cam | 30.57 | 0.71 | 1870.41 | 0 | 935.20 | 801.14 |
| LS | 32.42 | 0.78 | 6.03 | 22.67 | 14.355 | 34.67 |

Effectiveness of LS in Constrained Settings: The UAV-based surveillance system may require to operate in resource-constrained environment. In FIG. 24C, it is observed that the LS framework is much more suitable when it comes to functioning at extremely low memory space. On the other hand, the quality factor (defined above) of the traditional CAM is much lower and increases very slowly as the storage space limitation is relaxed.

### Dynamism of Various Embodiments

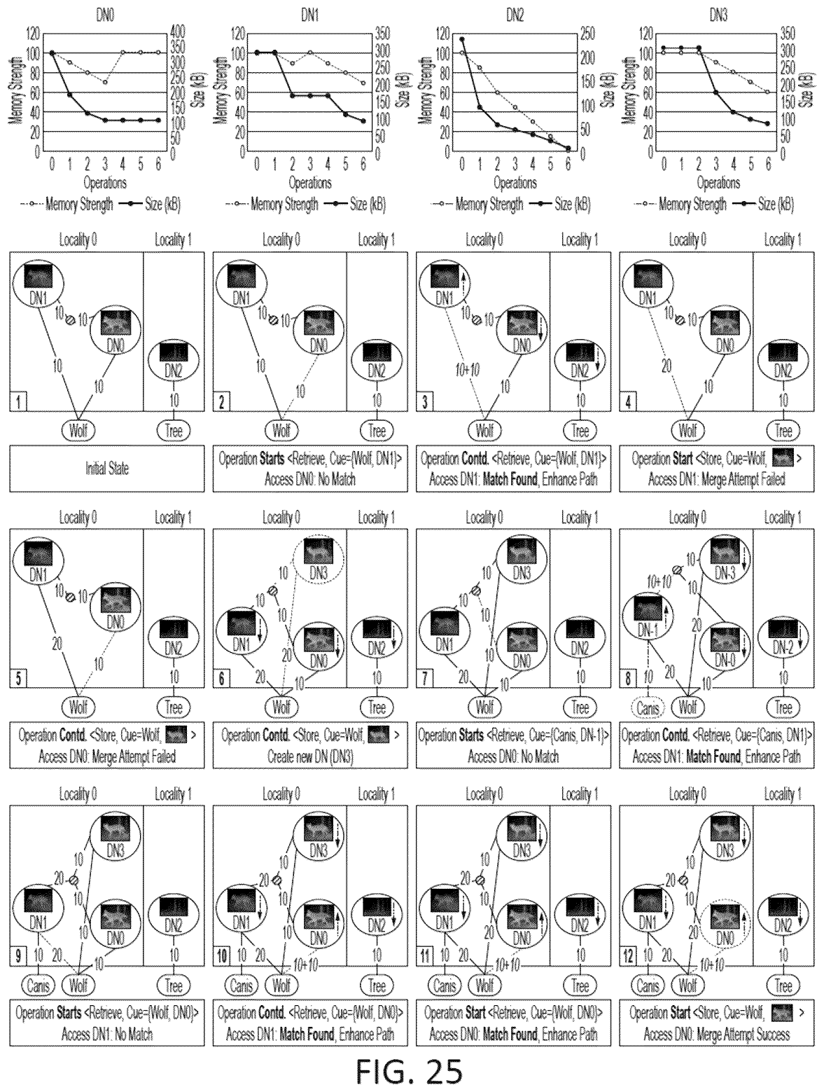

FIG. 25 illustrates visual examples of dynamism associated with embodiments of the present disclosure. Similar operation parameters and hyperparameters as used in the simulation configuration are used with the followings exceptions: Memory decay rate of each locality: [10, 20]; Mapping between data features and localities: All fox/wolf images are designated to stay in locality 0 and the rest are assigned to locality 1; Association weight adjustment parameter: 10; and Frequency of retention procedure: 1. The top 4 graphs in FIG. 25 depict the data object memory strength (Y-axis left) and size (Y-axis right) with respect to the number of operations performed (X-axis) for each of the 4 data objects in the scenario. The 12 snapshots (ID provided on the lower-left corner) in FIG. 25 are described below:
1. In the initial state, there are two data objects in locality 0 and one data object in locality 1.
2. The first operation starts with the coarse-grained cue “Wolf” and the fine-grained cue corresponding to the data-feature of DN1. Using the coarse-grained cue “Wolf”, the LS framework first compares the fine-grained cue with the data-feature of DN0. The matching fails due to lack of similarity.
3. In this step, the previous operation continues and the LS framework reaches DN1 using the coarse-grained cue “Wolf”. The fine-grained cue and data feature of DN1 matches leading to a successful retrieval. The weight of <Wolf, DN1> association is increased. Also, note that the memory strength of all data objects decreases and memory strength of DN1 is restored back to 100 (indicated by the red arrows).
4. The next operation is of type store. The cue provided is “Wolf” and a new data with nothing similar in the locality 0 is provided. The LS framework first attempts to merge the incoming data with an existing data object. The first match with DN1 fails because they are not similar. Note that DN1 is searched first because <Wolf,DN1> is greater than <Wolf, DN0>.
5. The match with DN0 also fails due to lack of data similarity.
6. Given that the merge attempt failed, a new data object DN3 is generated for the new incoming data. DN3 gets associated with the other DNs via the default cue object (cyan coloured circle in middle) and also gets associated with cue “Wolf”. Furthermore, the memory strength of all remaining data objects decreases.
7. The next operation is a retrieve operation with coarse-grained cue “Canis” and the fine-grained cue same as the data feature of DN1. There are no cue object for “Canis”, so the search is carried out via the default cue object (Locality-0). The first search yields DN0 which is not a good match.
8. The second search yields the correct output. The <default cue object, DN1> strength increase. A new cue object for “Canis” is generated and linked with DN1. Also, the memory strength of all data objects except DN1 decreases and memory strength of DN1 is restored back to 100.
9. The next operation is also a retrieve operation with coarse-grained cue “Wolf” and fine-grained cue same as data-feature of DN0. <DN1, Wolf> has the highest strength among other “Wolf” associations, so DN1 is compared with first. This however does not yield a good match.
10. The next data object searched is DN0 and a good similarity is found. The association <Wolf, DN0> increases in strength. Memory strength of DN0 is restored back to 100 and the memory strength of all remaining data objects decreases.
11. The next operation is of type retrieve with coarse-grained cue “Wolf” and fine-grained cue same as the data-feature of DN0. The association <Wolf, DN0> is explored first (because being first in the search order for cue “wolf”) and a good match is found. Memory strength of DN0 is restored back to 100 and the memory strengths of all remaining data objects decreases. Also, the <Wolf, DN0> association is strengthened.
12. The next operation is a store operation and a data very similar to DN0 is provided with cue “Wolf”. The first merge attempt with DN0 is a success and no new data object is generated for the incoming data. Memory strength of DN0 is restored back to 100 and the memory strengths of all remaining data objects decreases. Also, the <Wolf, DN0> association is strengthened.
13. In the DN0 graph (FIG. 25), it is observed that the data size and memory strength is maintained at a relatively high value throughout the case-study. This is because DN0 have been accessed the most among all data objects. For DN2 (background image in locality 1), the memory strength constantly decays at a higher rate due to lack of access and importance.

### Guided Tag Extraction

Various embodiments of the disclosure provide a method for automatically extracting tags from raw data stored inside a data graph. As used herein, a tag refers to metadata about a corresponding raw data unit. Embodiments herein provide a method for guided tag extraction utilizing generative artificial intelligence (GenAI) for Graph Based Intelligent Data Storage Systems. In at least some embodiments, such a method may be configured to extract metadata for an edge computing system as well as a cloud-based storage system for a target application. Guided tag extraction techniques as described herein may be utilized before system deployment and/or periodically during system operation after deployment.

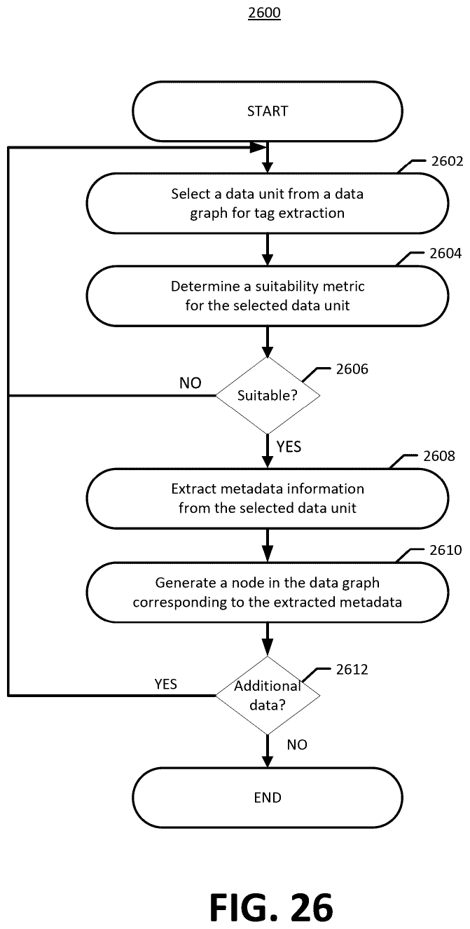

FIG. 26 illustrates a guided tag extraction method 2600 in accordance with at least some embodiments of the present disclosure. As depicted, guided tag extraction method 2600 includes selecting (2602) a data unit from a data graph for tag extraction, determining (2604) a suitability metric for the selected data unit, determining (2606) whether the suitability metric meets a threshold, extracting (2608) metadata information from the selected data unit, generating (2610) a node in the data graph corresponding to the extracted metadata, and determining (2612) whether additional stored data units exist which have not been subject to extraction. Guided tag extraction method 2600 may enable generative artificial intelligence guided metadata extraction with respect to a subject data graph. In at least some embodiments, a data retrieval module as described above (with respect to FIG. 5, for example) may additionally be configured for executing data extraction methods such as guided tag extraction method 2600.

At step 2602, the data retrieval module may select a data unit from a data graph for tag extraction. In at least some embodiments, selecting (2602) a data unit from a data graph for tag extraction includes selecting a data unit according to a priority order, wherein the priority order of data units is determined according to each data unit's impact on increased overall system performance. For example, a most important and relevant data unit (D) for which tag execution will lead to increased overall system performance may be a highest priority data unit, while a data unit with a minimal (or nonexistent) predicted impact on system performance may be a lower priority data unit. As such, selecting (2602) a data unit from a data graph for tag extraction may include selecting a most important data unit whose metadata has not yet been extracted.

At step 2604, the data retrieval module may determine a suitability metric for the selected data unit. Determining (2604) a suitability metric for the selected data unit may include calculating extraction suitability corresponding to the selected data unit with respect to the subject system. In at least some embodiments, the suitability metric for the selected data unit is determined according to an estimated cost necessary for the task relative to estimated benefits associated with the metadata extraction. In at least some embodiments, the suitability metric for the selected data unit is determined according to an estimated resource utilization necessary for the task relative to the estimated benefits associated with the metadata extraction. The suitability metric may be determined according to a combination of the estimated cost, resource utilization, and benefits of metadata extraction, and may be embodied as a real value “X” between 0 and 1 that describes the suitability for tag extraction for data unit D.

At step 2606, the data retrieval module may determine whether the suitability metric meets a threshold for extraction. In at least some embodiments, determining (2606) whether the suitability metric meets a threshold includes comparing the determined suitability metric for data unit D to a predefined threshold for proceeding with the metadata extraction. If it is determined that the suitability metric meets or exceeds the threshold (2606, yes branch), the method continues by extracting (2608) metadata information from the selected data unit. If it is determined that the suitability metric fails to meet or exceed the threshold (2606, no branch), the method continues by selecting (2602) a data unit from the data graph for tag extraction.

At step 2610, the data retrieval module may extract metadata (tag) information from the selected data unit D. In at least some embodiments, extracting (2608) metadata information from the selected data unit includes utilizing a generative artificial intelligence (AI) tag extraction model to extract metadata information from the selected data unit, wherein the extracted metadata may include information related to overall system performance. In at least some embodiments, the generative AI tag extraction model may be trained based on each iteration of the tag extraction. In at least some embodiments, the generative AI tag extraction model may be trained based on user feedback with respect to past iterations of the model's tag extraction results. In general, the generative AI tag extraction model is configured to automatically extract metadata from selected data unit D.

At step 2612, the data retrieval module may generate a node in the data graph corresponding to the extracted metadata. In at least some embodiments, generating (2610) a node in the data graph corresponding to the extracted metadata includes updating the data graph to include a node indicating the metadata and the data unit D to which it corresponds. In at least some embodiments, generating (2610) a node in the data graph corresponding to the extracted metadata includes generating a new data graph including a node corresponding to the metadata as well as the metadata's connection(s) to the nodes of the original data graph. In general, generating (2610) a node in the data graph corresponding to the extracted metadata includes creating, updating, or otherwise providing a data graph including an indication of the extracted metadata and its relationship(s) to the nodes of the original data graph.

At step 2612, the data retrieval module may determine whether additional stored data units exist which have not been subject to extraction. Determining (2612) whether additional stored data units exist which have not been subject to extraction may include determining whether all available metadata has been extracted from the nodes of the data graph. In at least some embodiments, determining (2612) whether additional stored data units exist may include whether any data units remain which (i) have not been subjected to metadata extraction and (ii) meet the suitability threshold for extraction. If additional units indeed remain (2612, yes branch), the method continues by returning to selecting (2602) a data unit from the data graph for tag extraction If no additional data units remain (2612, no branch), the method concludes.

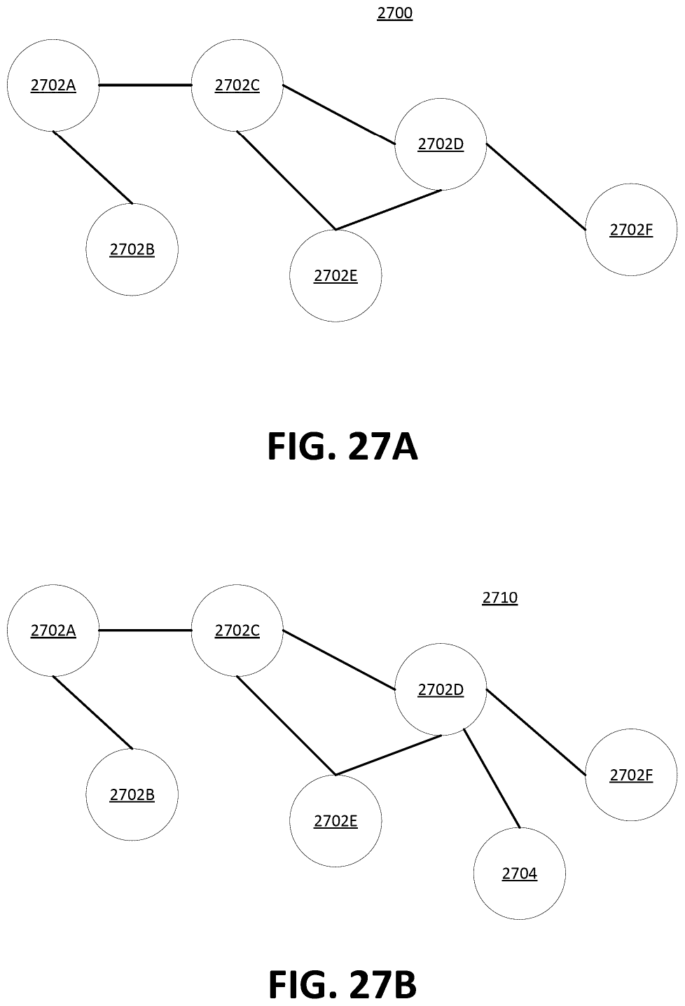

FIG. 27A illustrates an initial data graph 2700 in accordance with at least some embodiments of the present disclosure. As depicted, initial data graph 2700 includes a plurality of data units (or data nodes) 2702 (2702A, 2702B, 2702C, 2702D, 2702E, 2702F). Initial data graph 2700 additionally depicts the connections/edges between the data units 2702. FIG. 27B depicts an updated data graph 2710 comprising the same plurality of data units (or data nodes) 2702 (2702A, 2702B, 2702C, 2702D, 2702E, 2702F) along with a metadata node 2704. As depicted, the metadata node 2704 is connected to data node 2702D, indicating that the metadata of metadata node 2704 was extracted from data node 2702D.

### Potential Application of Various Embodiments

As noted, various embodiments of the disclosure can replace the memory system in many applications. By setting the initialization parameters correctly, various embodiments can provide optimal performance that can adapt and improve over time based on learning memory concepts. Examples of applications are discussed below to demonstrate the use of various embodiments of the disclosure for these applications.

### Wildlife Detection System (Image+Sound)

In a wildlife detection/surveillance system, cameras are spread across the wilderness to capture rare glimpses of wild animals. Oftentimes, these cameras are capturing footage of the forest that is not of much interest, resulting in huge memory storage requirements. Also, sending large amounts of data of little interest in wireless mode can cause remote devices used in such systems to discharge very quickly. Accordingly, various embodiments can be used in this scenario to optimize wildlife capture. For example, various embodiments can provide multiple hives 110, 120 for storage. For instance, one hive 110 with multiple localities 111, 113 for sound and one hive 120 with multiple localities 121, 123 for images.

In addition, various embodiments can use AI model(s) trained to extract image and/or sound features from wildlife datasets. Here, sound with features related to wild animals can be stored in a first locality 111 of a hive 110 and images with features related to wild animals can be stored in a second locality 121 of a hive 120. While sound with features not related to wild animals can be stored in a second, different locality 113 of the hive 110 and images with features not related to wild animals can be stored in a second, different locality 123 of the hive 120. Accordingly, the localities 111, 121 in the hives 110, 120 used to store the sounds and images related to wild animals can have slower memory strength decay to allow for more precise retention of wild animal data. While the background sound and images data not related to wild animals can be compressed over time. Faster searching can also occur due to data unit merging resulting in limiting the number of memory entries and intelligent data unit and cue association management. As a result, searching for wild animal data can become easier due to such data being stored inside separate localities 111, 121 for both the hives 110, 120.

### Poacher Detection System (Image+Sound)

Poaching of endangered animals is harmful for the ecosystem. Accordingly, poacher detection systems may be placed in many reserved forest and jungles. However, such systems are forced to store huge amounts of unnecessary data. This can result in huge storage requirements. Also, sending unneeded data in wireless mode can cause remote devices used in such systems to discharge very quickly. Accordingly, for the reasons discussed above with the advantages of using various embodiments of the disclosure in systems for wildlife detection, such advantages can be realized from using various embodiments in poacher detection systems.

### Home Security System (Video+Sound)

Home security systems are extremely popular and useful. However, such systems have severe limitations in terms of how much data they can store at any given time. Also, sending unneeded data in wireless mode can cause remote devices used in such systems to discharge very quickly. Accordingly, for the reasons discussed above with the advantages of using various embodiments of the disclosure in systems for wildlife detection, such advantages can be realized from using various embodiments in home security systems.

### Forest Fire Detection System (Image+Sound)

Forest fire detection using drones will benefit from various embodiments of the disclosure. Here, the drones are forced to store huge amounts of unnecessary data. This can result in huge storage requirements. Also, sending unneeded data in wireless mode can cause the drones and/or remote devices used in such systems to discharge very quickly. Accordingly, for the reasons discussed above with the advantages of using various embodiments of the disclosure in systems for wildlife detection, such advantages can be realized from using various embodiments in forest fire detection systems.

### Agricultural Automation

Automation in agriculture such as weed detection, aerial phenotyping, and agriculture pattern analysis requires storing and subsequent analysis of huge amount of image data. A dynamic, intelligent and virtually infinite memory framework according to embodiments herein can adapt to the demand while providing optimal performance.

### Post-Disaster Infrastructure Inspection

Automatic detection techniques for inspecting infrastructure damages due to natural disasters such as earthquake and hurricane are being widely explored. Most of these techniques deal with a huge influx of data that may not be always relevant to the task. An intelligent memory framework according to embodiments herein can optimize the entire data retention process to boost overall system performance.

### Maritime Surveillance

Detecting and monitoring maritime activities often involve SAR (Synthetic-aperture radar) data, standard radar data, infrared data and video data. Efficiently handling this huge amount of multi-modal data is crucial for success and a framework according to embodiments herein would be ideal for such applications.

### Space and Remote Planet Exploration

Space observation facilities and planet exploration systems (such as the MARS Rover) deal with huge influx of data. With limited space, energy and bandwidth constraints it is crucial to store and transmit efficiently. A framework according to embodiments herein can certainly boost the efficiency of such a system.

### Conclusion

Embodiments herein present a new paradigm of learning computer memory that can track data access patterns to dynamically organize itself for providing high efficiency in terms of data storage and retrieval performance. The learnable parameters and the learning process are present herein, which are incorporated into the operations. Embodiments herein enable selection and customization for a target application.

Many modifications and other embodiments of the disclosures set forth herein will come to mind to one skilled in the art to which these disclosures pertain having the benefit of the teachings presented in the foregoing descriptions and the associated drawings. Therefore, it is to be understood that the disclosures are not to be limited to the specific embodiments disclosed and that modifications and other embodiments are intended to be included within the scope of the appended claims. Although specific terms are employed herein, they are used in a generic and descriptive sense only and not for purposes of limitation.

### Appendix of Example Algorithms

Algorithm 1 Store

| | |
|---|---|
| 1: | procedure STORE(M, D, S. SearchLimit, up, k) |
| 2: | DT = D → Data_Type |
| 3: | MH = select_Hive(M, DT) |
| 4: | Params = MH → Params |
| 5: | η = Params → Assoc_Wt_Adj |
| 6: | DF = D → Features |
| 7: | C = S → Search_Cues |
| 8: | T1 = S → Assoc_Thresh |
| 9: | T2 = S → Match_Thresh |
| 10: | C_ext = extract_Cue(Params, D) |
| 11: | C.append(C_cat) |
| 12: | elasticity_iter = 0 |
| 13: | while size(D) > remaining_space(MH) do |
| 14: | ELASTICITY (elasticity_iter, MH) |
| 15: | elasticity_iter + + |
| 16: | L = select_Locality(Params, C, D) |
| 17: | found = False |
| 18: | SO = GET_SEARCH_ORDER(C, MH, T1, SearchLimit) |
| 19: | index = 0 |
| 20: | DN_List = ϕ |
| 21: | while found = = False && index <= SearchLimit do |
| 22: | {Path, TargetDN} = SO[index] |
| 23: | if TargetDN ∉ DN_List then |
| 24: | if match(TargetDN → DF, DF) > T2 then |
| 25: | found = True |
| 26: | REACTION (MH, TargetDN, Path, η, 1, C, up, k) |
| 27: | else |
| 28: | REACTION (MH, TargetDN, Path, η, 0, G, up, k) |
| 29: | DN_List.append(TargetDN) |
| 30: | index + + |
| 31: | if found = = False then |
| 32: | DN_New ::: Initialize New DN with D in L |
| 33: | for each c ∈ [symbol] do |
| 34: | associate(c. DN_New) |
| 35: | UPDATE_MEMORY_SEARCH_ORDER(MH) |

Algorithm 2 Retrieve

| | |
|---|---|
| 1: | procedure RETRIEVE(M, S, SearchLimit, up, k) |
| 2: | DT = S → Data_Type |
| 3: | MH = select_Hive(M, DT) |
| 4: | Params = MH → Params |
| 5: | η = Params → Assoc_Wt_Adj |
| 6: | C = S → Search_Cues |
| 7: | C_ext = extract_Cue(S → Ref_D) |
| 8: | C.append(C_ext) |
| 9: | C1 = C → Search_Cues_Coarse |
| 10: | C2 = S → Search_Cues_Fine |
| 11: | T1 = S → Assoc_Thresh |
| 12: | T2 = S → Match_Thresh |
| 13: | found = False |
| 14: | DN_List = ϕ |
| 15: | Ret_Data = ϕ |
| 16: | SO = GET_SEARCH_ORDER(C1, MH, T1, SearchLimit) |
| 17: | index = 0 |
| 18: | while found = = False && index <= SearchLimit do |
| 19: | {Path, TargetDN} = SO[index] |
| 20: | if TargetDN ∉ DN_List then |
| 21: | if match(TargetDN, C2) > T2 then |
| 22: | found = True |
| 23: | REACTION(MH, TargetDN, Path, η, 1, C, up, k) |
| 24: | Ret_Data = TargetDN → Data |
| 25: | else |
| 26: | REACTION(MH, TargetDN, Path, η, 0, C, up, k) |
| 27: | DN_List.append(TargetDN) |
| 28: | index + + |
| 29: | return Ret_Data |

Algorithm 3 Retention

| | |
|---|---|
| 1: | procedure RETENTION(M, N, k) |
| 2: | C = M → Connections |
| 3: | D = M → Data_Neurons |
| 4: | if k = = 1 then |
| 5: | for each c ∈ [symbol] do |
| 6: | if Not_Accessed_Recently(c, N) then |
| 7: | MH_ID = Find_Memory_Hive_ID(c) |
| 8: | L_ID = Find_Memory_Locality_ID(c) |
| 9: | a_decay = Find_Assoc_Decay(MH_ID, L_ID, M) |
| 10: | Weaken(C, a_decay) |
| 11: | for each d ∈ [symbol] do |
| 12: | If Not_Accessed_Recently(d, N) then |
| 13: | MH_ID = Find_Memory_Hive_ID(d) |
| 14: | L_ID = Find_Memory_Locality_ID(d) |
| 15: | d_decay = Find_Mem_Decay(MH_ID, L_ID, M) |
| 16: | imp_degree = Find_Imprec_Degree(MH_ID) |
| 17: | d_str_new = reduce_mem_str(d, d_decay) |
| 18: | Compress_Mem(d, d_str_new, imp_degree) |
| 19: | for each MH ∈ [symbol] do |
| 20: | UPDATE_MEMORY_SEARCH_ORDER(M H) |

Algorithm 4 Reaction

| | |
|---|---|
| 1: | procedure REACTION(M H, TargetDN, Path, η, flag, C, up, k) |
| 2: | for each a ∈ [symbol] ath do |
| 3: | if flag = = 1 then |
| 4: | Increase_Assoc_Weight(a, η) |
| 5: | if flag = = 0 && k = = 1 then |
| 6: | Decrease_Assoc_Weight(a, η) |
| 7: | if flag = = 1 then |
| 8: | Increase_Mem_Str(TargetDN) |
| 9: | for each Cᵢ ∈ [symbol] do |
| 10: | associate_enhance(Cᵢ, TargetDN) |
| 11: | if up = = 1 then |
| 12: | UPDATE_MEMORY_SEARCH_ORDER(M H) |

Algorithm 5 Elasticity

| | |
|---|---|
| 1: | procedure ELASTICITY(elasticity_iter, MH) |
| 2: | elast_param = MH → Params → elast_param |
| 3: | imp_degree = Find_Imprec_Degree(MH_ID) |
| 4: | for each L ∈ [symbol] H do |
| 5: | ef = elast_param[L → Index][elasticity_iter] |
| 6: | for each D ∈ [symbol] do |
| 7: | d_str_new = Decrease_Mem_Str(D, ef) |
| 8: | Compress_Mem(D, d_str_new, imp_degree) |

Algorithm 6 Get Search Order

| | |
|---|---|
| 1: | procedure GET_SEARCH_ORDER(C, MH, T1, SearchLimit) |
| 2: | CandidateList = ϕ |
| 3: | Count = 0 |
| 4: | for each Cᵢ ∈ [symbol] do |
| 5: | SO = MH → Search_Order[Cᵢ → Index] |
| 6: | for each candidate ∈ [symbol] O so |
| 7: | if candidate → assoc_Str > T1 then |
| 8: | CandidateList.append(candidate) |
| 9: | Count + + |
| 10: | if Count >= SearchLimit then |
| 11: | return CandidateList |
| 12: | else |
| 13: | Break Loop |
| 14: | return CandidateList |

Algorithm 7 Update Memory Search Order

| | |
|---|---|
| 1: | procedure UPDATE_MEMORY_SEARCH_ORDER(MH) |
| 2: | Cues = MH → Cues |
| 3: | NewSearchOrder = ϕ |
| 4: | for each C ∈ [symbol] ues do |
| 5: | cueSearchOrder = ϕ |
| 6: | D = All data-neuron reachable from C |
| 7: | for each Dᵢ ∈ [symbol] do |
| 8: | SP = find_Average_Strongest_path(C, Dᵢ) |
| 9: | assoc_Str = average_Assoc_Str(SP) |
| 10: | insert_Sort(cueSearchOrder, DU, SP, assoc_Str) |
| 11: | NewSearchOrder[C → Index] = cueSearchOrder |
| 12: | MH → Search_Order = NewSearchOrder |

1. A method for implementing a digital memory system, the method comprising:
selecting, using one or more processors, locations of one or more memory subsystems components of the digital memory system for storage of one or more hives, wherein a hive of the one or more hives stores data of a particular modality;
selecting, using the one or more processors, first locations of the hive for storage of one or more localities for the hive, wherein a locality of the one or more localities for the hive comprises one or more data units that are one or more of semantically related or interconnected based on a relation to each other;
selecting, using the one or more processors, second locations of the hive for storage of at least one cue bank for the hive, wherein the at least one cue bank is configured to store cue objects configured to semantically link one or more data units across the one or more localities for the hive;
generating, using the one or more processors and for the hive, an inter-data unit connectivity graph comprising a plurality of nodes and a plurality of edges, wherein a node of the plurality of nodes represents a cue object of the hive and an edge of the plurality of edges represents an association between a first node representing a first cue object and a second node representing a second cue object; and
adjusting, using the one or more processors, the inter-data unit connectivity graph according to changes in associations between the cue objects of the hive, wherein the associations are one or more of generated, deleted, strengthened, or weakened based at least in part on memory operations over time.

2. The method of claim 1, wherein a data unit of the one or more data units comprises one or more of a data element, features of the data element, or parameters relevant to the data element.

3. The method of claim 1, further comprising:
selecting an appropriate hive from the one or more hives for a new data element based on a data type for the new data element;
extracting one or more features of the new data element;
selecting an appropriate locality from the one or more localities for the appropriate hive based on the one or more features of the new data element; and
responsive to the new data element being similar within a merge threshold to a data element of an appropriate data unit of the one or more data units for the appropriate locality:
merging the new data element with the appropriate data unit of the one or more data units for the appropriate locality; and
performing at least one of (1) increasing a memory strength identifying a retention quality for the appropriate data unit and an accessibility for the appropriate data unit or (2) changing a location of the appropriate data unit within the appropriate locality with respect to one or more remaining data units for the appropriate locality to increase the accessibility for the appropriate data unit.

4. The method of claim 1, further comprising:
selecting an appropriate hive from the one or more hives for a new data element based on a data type for the new data element;
extracting one or more features of the new data element;
selecting an appropriate locality from the one or more localities for the appropriate hive based on the one or more features of the new data element; and
responsive to the new data element not being similar within a merge threshold to a data element of any data unit of the one or more data units for the appropriate locality:
initializing a new data unit for the new data element;
setting a memory strength for the new data unit; and
placing the new data unit comprising the new data element at a location in the appropriate locality with respect to the one or more data units for the appropriate locality to set an accessibility for the new data unit.

5. The method of claim 1, further comprising:
reading a query data type, one or more query features, one or more query cues, and at least one of a matching threshold and a number of maximum matches;
selecting an appropriate hive from the one or more hives based on the query data type;
selecting an entry point for the appropriate hive based on the one or more query cues; and
while traversing the appropriate hive starting at the entry point:
performing at least one of (1) selecting the one or more data units having features similar to the one or more query features over the matching threshold from the one or more localities for the appropriate hive or (2) selecting a first number of data units equal to the number of maximum matches of the one or more data units having features similar to the one or more query features over the matching threshold from the one or more localities for the appropriate hive; and
performing at least one of (1) increasing a memory strength identifying a retention quality and an accessibility for at least one of the selected one or more data units or (2) changing a location of at least one of the selected one or more data units within the locality for the at least one of the selected data units with respect to one or more remaining data units for the locality to increase the accessibility for an appropriate data unit.

6. The method of claim 1, further comprising:
selecting a data unit from the one or more data units for a locality from the one or more localities for a hive of the one or more hives;
increasing an age of the data unit;
decreasing a memory strength identifying a retention quality and an accessibility for the data unit;
applying at least one of a feature deduction and feature compression on features of the data unit based on the age and the memory strength; and
adjusting a connectivity of the data unit within the locality.

7. The method of claim 1, wherein the cue objects stored for the at least one cue bank for at least one hive are configured as at least one of a hierarchical network of cue objects and heterogeneous cue objects to allow for more efficient and flexible search of the one or more data units.

8. The method of claim 1, wherein each of the one or more localities for each hive of the one or more hives comprises a retention ability for retaining data and a search priority specified by at least one of a user and statistical information.

9. The method of claim 1, wherein each data unit of the one or more data units for each locality for each hive comprises a memory strength identifying a retention quality for the data unit and an accessibility for the data unit.

10. The method of claim 9, wherein the memory strength of each of the one or more data units decays with time at a rate specified by at least one of a user and statistical information.

11. The method of claim 9, wherein the memory strength of each of the one or more data units increases as a result of at least one of a data unit being accessed and a data unit being merged with another one of the one or more data units.

12. The method of claim 1, further comprising:
assigning new data to one of the one or more localities for one of the one or more hives based on a mapping between certain features of new data and the one of the one or more localities.

13. An apparatus comprising at least one processor and at least one memory storing instructions that, with the at least one processor, configure the apparatus to:
select locations of one or more memory subsystem components of a digital memory system for storage of one or more hives, wherein each hive of the one or more hives stores data of a particular modality;
select first locations of each hive for storage of one or more localities for the hive, wherein each locality of the one or more localities for each hive comprises one or more data units that are one or more of semantically related or interconnected based on a relation to each other;
select second locations of each hive for storage of at least one cue bank for the hive, wherein the at least one cue bank is configured to store cue objects configured to semantically link one or more data units across the one or more localities for a particular hive;
generate, for each hive of the one or more hives, an inter-data unit connectivity graph comprising a plurality of nodes and a plurality of edges, wherein each node of the plurality of nodes represents a cue object of the hive and an edge of the plurality of edges represents an association between a first node representing a first cue object and a second node representing a second cue object; and
adjust the inter-data unit connectivity graph according to changes in associations between the cue objects of the hive, wherein the associations are one or more of generated, deleted, strengthened, or weakened based at least in part on memory operations over time.

14-23. (canceled)

24. A non-transitory computer-readable storage medium comprising computer code that, when executed by one or more processors of an apparatus, cause the apparatus to:
select locations of one or more memory subsystem components of a digital memory system for storage of one or more hives, wherein each hive of the one or more hives stores data of a particular modality;
select first locations of each hive for storage of one or more localities for the hive, wherein each locality of the one or more localities for each hive comprises one or more data units that are one or more of semantically related or interconnected based on a relation to each other;
select second locations of each hive for storage of at least one cue bank for the hive, wherein the at least one cue bank is configured to store cue objects configured to semantically link one or more data units across the one or more localities for a particular hive;
generate, for each hive of the one or more hives, an inter-data unit connectivity graph comprising a plurality of nodes and a plurality of edges, wherein each node of the plurality of nodes represents a cue object of the hive and an edge of the plurality of edges represents an association between a first node representing a first cue object and a second node representing a second cue object; and
adjust the inter-data unit connectivity graph according to changes in associations between the cue objects of the hive, wherein the associations are one or more of generated, deleted, strengthened, or weakened based at least in part on memory operations over time.

25. The method of claim 1, further comprising:
selecting a node of the plurality of nodes from the inter-data unit connectivity graph;
determining an extraction suitability metric of the selected data node based, at least in part, on an estimated benefit of extracting metadata from the selected data node;
determining whether the extraction suitability metric of the selected data node meets or exceeds a defined suitability threshold;
extracting, from one or more raw data units of the selected data node and using a generative artificial intelligence (AI) model, metadata corresponding to the one or more raw data units; and
generating an updated inter-data unit connectivity graph including a metadata node corresponding to the extracted metadata connected to the selected data node.

26. The method of claim 25, wherein the extraction suitability metric is further determined according to an estimated cost associated with extracting metadata from the selected data node.

27. The method of claim 25, wherein the extraction suitability metric is further determined according to an estimated resource utilization necessary for executing metadata from the selected data node.

28. The method of claim 25, wherein the extraction suitability metric is a value between 0 and 1.

29. The method of claim 25, wherein generating an updated inter-data unit connectivity graph includes updating the inter-data unit connectivity graph to include the node corresponding to the extracted metadata connected to the selected data node.

30. The method of claim 25, wherein generating an updated inter-data unit connectivity graph includes generating a new inter-data unit connectivity graph including the metadata node corresponding to the extracted metadata connected to the selected data node.
